(19) United States
(12) Patent Application Publication
(10) Pub. No.: US 2025/0031543 A1
(43) Pub. Date: Jan. 23, 2025

(54) TILING DISPLAY, UNIT PANEL GROUP, METHOD FOR PRODUCING TILING DISPLAY, AND METHOD FOR MAINTAINING TILING DISPLAY

(71) Applicant: AGC Inc., Tokyo (JP)

(72) Inventors: Kazuya TAKEMOTO, Tokyo (JP); Katsumi SUZUKI, Tokyo (JP)

(73) Assignee: AGC Inc., Tokyo (JP)

(21) Appl. No.: 18/908,312

(22) Filed: Oct. 7, 2024

Related U.S. Application Data
(63) Continuation of application No. PCT/JP2023/014149, filed on Apr. 5, 2023.

(30) Foreign Application Priority Data
Apr. 8, 2022 (JP) 2022-064751
Apr. 8, 2022 (JP) 2022-064752
Jul. 13, 2022 (JP) 2022-112709
Nov. 29, 2022 (JP) 2022-190437

(51) Int. Cl. H10K 59/18; H10K 59/80

(52) U.S. Cl. CPC H10K 59/18; H10K 59/8792

(57) ABSTRACT

A tiling display is obtained by arranging a plurality of unit panels, each including an anti-reflective film-attached transparent substrate on a display surface side. The anti-reflective film-attached transparent substrate includes a transparent substrate, a diffusion layer, and an anti-reflective film in this order toward the display surface side, and two of the unit panels adjacent to each other satisfy the condition 1.

### CROSS-REFERENCE TO RELATED APPLICATIONS

This is a bypass continuation of International Patent Application No. PCT/JP2023/014149, filed on Apr. 5, 2023, which claims priority to Japanese Patent Application No. 2022-064751, filed on Apr. 8, 2022, Japanese Patent Application No. 2022-064752, filed on Apr. 8, 2022, Japanese Patent Application No. 2022-112709, filed on Jul. 13, 2022, and Japanese Patent Application No. 2022-190437, filed on Nov. 29, 2022. The contents of these applications are hereby incorporated by reference in their entireties.

### TECHNICAL FIELD

The present invention relates to a tiling display, a unit panel group, a method for producing a tiling display, and a method for maintaining a tiling display.

### BACKGROUND ART

In recent years, a method of installing a transparent substrate such as a cover glass on a front surface of an image display device such as a liquid crystal display (LCD) has been used from the viewpoint of aesthetic appearance. In order to prevent glare from an external light on such a transparent substrate, a transparent substrate provided with an anti-reflective film (hereinafter, also referred to as an anti-reflective film-attached transparent substrate) is known. For example, Patent Literature 1 discloses an anti-reflective film-attached transparent substrate, which has a light absorption ability and an insulating property.

In addition, in order to prevent the glare from the external light, it is also known to provide a diffusion layer on the transparent substrate. The diffusion layer diffuses the incident light to prevent the glare from the external light. Examples of a method of providing the diffusion layer include a method of attaching a film having a diffusion layer (anti-glare film) on a main surface of a transparent substrate or a panel of an image display device.

In the case where the transparent substrate includes a diffusion layer and is used in an image display device, the screen may appear whitish due to the diffused light when turned off. Therefore, it is also conceivable to further provide the anti-reflective film as described above on the diffusion layer. Accordingly, reflection of the incident light can be prevented and whiteness is reduced, so that the glare can be suitably prevented while improving a black texture when the screen is turned off.

In recent years, there has been a demand for a larger screen for displays. When attempting to achieve a large-screen display using a single display panel, problems may arise from the viewpoint of mechanical strength and from the viewpoint of display unevenness due to increased resistance of electrodes. In contrast, it is being considered to achieve a large screen by forming a display element into a panel shape and arranging a plurality of panels as unit panels in a tiled manner (tiling).

For example, Patent Literature 2 discloses a tiling display obtained by arranging, in a tiled manner, a plurality of unit panels, each having a non-display region around a periphery, in which a display sheet using an organic LED as a surface light source is arranged to cover the non-display region between adjacent unit panels.

### CITATION LIST

### Patent Literature

Patent Literature 1: JP2018-115105A
Patent Literature 2: JP2007-192977A

### SUMMARY OF INVENTION

### Technical Problem

However, in the case where the unit panels constituting the tiling display each include an anti-reflective film-attached transparent substrate or an anti-glare film, depending on an angle from which the tiling display is viewed, an object color (diffusion reflection color) on the anti-reflective film-attached transparent substrate or the anti-glare film may appear different for respective unit panels. In this case, a color deviation between the unit panels is noticeable, and the quality of the tiling display may be greatly reduced, for example, causing the appearance to vary in color during turning-off.

Therefore, an object of the present invention is to provide a tiling display with a less noticeable color deviation, a unit panel group for use in the tiling display, a method for producing a tiling display, and a method for maintaining a tiling.

### Solution to Problem

The inventors of the present invention have found that in the case where unit panels constituting a tiling display each include an anti-reflective film-attached transparent substrate, focusing on a color tone (a* and b*) of a diffusely reflected light when a light is incident on a main surface on a display surface side of the unit panel at a predetermined angle, when the a* and the b* of diffusely reflected lights at a plurality of angles are set to satisfy a predetermined condition between adjacent unit panels, a tiling display with a less noticeable color deviation can be obtained. Thus, the present invention has been completed.

In addition, the inventors of the present invention have found that in the case where unit panels constituting a tiling display each include an anti-glare film, focusing on directivity of anti-glare properties in the anti-glare film, when an index of the anti-glare properties on a main surface on a display surface side of the unit panel is set to satisfy a predetermined condition between adjacent unit panels, a tiling display with a less noticeable color deviation can be obtained. Thus, the present invention has been completed.

That is, the present invention relates to the following 1 to 10.

1. A tiling display including:
a plurality of unit panels, each including an anti-reflective film-attached transparent substrate on a display surface side,
in which the anti-reflective film-attached transparent substrate includes a transparent substrate, a diffusion layer, and an anti-reflective film in this order toward the display surface side, and two of the unit panels adjacent to each other satisfy the condition 1 to be described later.

2. The tiling display according to the above 1, in which the anti-reflective film-attached transparent substrate has a haze value of 30% or more.

3. A unit panel group for use in a tiling display obtained by arranging a plurality of unit panels, each including an anti-reflective film-attached transparent substrate on a display surface side,
in which the anti-reflective film-attached transparent substrate includes a transparent substrate, a diffusion layer, and an anti-reflective film in this order toward the display surface side, and any two unit panels selected from the unit panel group satisfy the condition 1 to be described later.

4. The unit panel group according to the above 3, in which the anti-reflective film-attached transparent substrate has a haze value of 30% or more.

5. A method for producing a tiling display obtained by arranging a plurality of unit panels, each including an anti-reflective film-attached transparent substrate on a display surface side, the method including:
determining a* and b* of diffusely reflected lights at angles of −15°, 15°, and 25° with respect to a specularly reflected light under a D65 light source when a light source is incident at an incident angle of 45° on a main surface on the display surface side of the plurality of unit panels; and
selecting a combination of unit panels that satisfies the condition 1 to be described later, and arranging the unit panels corresponding to the combination adjacent to each other.

6. A method for maintaining a tiling display obtained by arranging a plurality of unit panels, each including an anti-reflective film-attached transparent substrate on a display surface side, the method including:
selecting a unit panel to be replaced from the unit panels constituting the tiling display;
determining a* and b* of diffusely reflected lights at angles of −15°, 15°, and 25° with respect to a specularly reflected light under a D65 light source when a light source is incident at an incident angle of 45° on a main surface on the display surface side of at least one adjacent unit panel adjacent to the unit panel to be replaced; and
replacing the unit panel to be replaced such that a unit panel after replacement and the adjacent unit panel satisfy the condition 1 to be described later.

7. The tiling display according to the above 1 or 2, in which the anti-reflective film-attached transparent substrate includes an anti-glare film as the diffusion layer and the transparent substrate, and the two adjacent unit panels satisfy the condition 2 to be described later.

8. A tiling display obtained by arranging a plurality of unit panels, each including an anti-glare film on a display surface side, in which two of the unit panels adjacent to each other satisfy the condition 2 to be described later.

9. A method for producing a tiling display obtained by arranging a plurality of unit panels, each including an anti-glare film on a display surface side, the method including arranging the unit panels such that the unit panels adjacent to each other satisfy the condition 2 to be described later.

10. A method for maintaining a tiling display obtained by arranging a plurality of unit panels, each including an anti-glare film on a display surface side, the method including:
selecting a unit panel to be replaced from the unit panels constituting the tiling display; and
replacing the unit panel to be replaced such that a unit panel after replacement and at least one adjacent unit panel adjacent to the unit panel to be replaced satisfy the condition 2 to be described later.

In the above 1 to 7, the condition 1 is as follows.

### (Condition 1)

Provided that a* and b* of diffusely reflected lights at angles of −15°, 15°, and 25° with respect to a specularly reflected light under a D65 light source when a light source is incident at an incident angle of 45° on a main surface on the display surface side for one unit panel of the two unit panels are defined as aₓ* and bₓ* at respective angles, and a* and b* for the other unit panel measured in the same manner are defined as a_{y}* and b_{y}* at respective angles, Δa*b* at respective angles is 3.0 or less.

$$Δ {a}^{*} {b}^{*} = {( {( {a}_{x}^{*} - {a}_{y}^{*} )}^{2} + {( {b}_{x}^{*} - {b}_{y}^{*} )}^{2} )}^{1 / 2}$$

In the above 7 to 10, the condition 2 is as follows.

### (Condition 2)

A difference between an angle in a direction where an L* value is maximum for one unit panel of the two adjacent unit panels and an angle in a direction where an L* value is maximum for the other unit panel measured in the same manner is 35° or less, as obtained by the following method.

### (Method)

In a plane parallel to a main surface of the tiling display, one direction of directions parallel to a side shared by the two adjacent unit panels is defined as a 0° direction. A light source is incident on a main surface on the display surface side of a unit panel to be measured at an incident angle of 45° while changing an incident direction from the 0° direction to a 360° direction at an interval of 10°. An L* value of a diffusely reflected light at an angle of −15° with respect to a specularly reflected light of an incident light under a D65 light source is measured at each incident direction, and an angle in the incident direction where the L* value is maximum is defined as the angle in the direction where the L* value is maximum for the unit panel to be measured.

### Advantageous Effects of Invention

According to the aspect of the present invention, it is possible to provide a tiling display with a less noticeable color deviation, a unit panel group for use in the tiling display, a method for producing a tiling display, and a method for maintaining a tiling display. When the color deviation is less noticeable, the quality and the aesthetic appearance of the tiling display can be improved.

### BRIEF DESCRIPTION OF DRAWINGS

FIG. 1 is a perspective view schematically showing a configuration example of a tiling display according to a first embodiment of the present invention.

FIG. 2 is a cross-sectional view schematically showing a configuration example of an anti-reflective film-attached transparent substrate in a unit panel.

FIG. 3 is a schematic diagram illustrating a method of measuring a* and b* of a diffusely reflected light at each angle according to a condition 1.

FIG. 4 is a schematic diagram illustrating a method of measuring a* and b* of a diffusely reflected light at each angle according to conditions A to D.

FIG. 5 is a perspective view schematically showing a configuration example of a tiling display according to a second embodiment of the present invention.

FIG. 6 is a cross-sectional view schematically showing a configuration example of a unit panel including an anti-glare film.

FIG. 7 is a diagram schematically showing a measurement method according to a condition 2.

FIG. 8 is a diagram showing measurement results of a tiling display in Example 3 according to the condition 2.

FIG. 9 is a diagram showing measurement results of a tiling display in Example 4 according to the condition 2.

FIG. 10 is a diagram showing measurement results of a tiling display in Example 5 according to the condition 2.

### DESCRIPTION OF EMBODIMENTS

Hereinafter, the present invention is described in detail, but the present invention is not limited to the following embodiments, and can be freely modified and implemented without departing from the gist of the present invention. In addition, “to” indicating a numerical range is used to include numerical values written before and after it as a lower limit value and an upper limit value.

Note that, in the present description, “another layer, film, or the like being provided on a main surface of a substrate such as a transparent substrate, on a layer such as diffusion layer, or on a film such as an anti-reflective film” is not limited to an embodiment in which the another layer, film, or the like is provided in contact with the main surface, layer, or film, but may be an embodiment in which the layer, film, or the like is provided in an upward direction. For example, “including a diffusion layer on a main surface of a transparent substrate” means that the diffusion layer is provided in contact with the main surface of the transparent substrate, or any other layer, film, or the like may be provided between the transparent substrate and the diffusion layer.

In the present description, unless otherwise specified, a*, b* and L* respectively refer to a*, b* and L* under a D65 light source.

In the following drawings, members and portions having the same functions may be denoted by the same reference numerals, and duplicate descriptions may be omitted or simplified. In addition, embodiments described in the drawings are schematically for the purpose of clearly illustrating the present invention, and do not necessarily accurately represent a size or a scale of an actual device.

### First Embodiment

### (Tiling Display)

A tiling display according to a first embodiment of the present invention is a tiling display obtained by arranging a plurality of unit panels, each including an anti-reflective film-attached transparent substrate on a display surface side, in which the anti-reflective film-attached transparent substrate includes a transparent substrate, a diffusion layer, and an anti-reflective film in this order toward the display surface side, and two of the unit panels adjacent to each other satisfy the following condition 1.

### (Condition 1)

provided that a* and b* of diffusely reflected lights at angles of −15°, 15°, and 25° with respect to a specularly reflected light under a D65 light source when a light source is incident at an incident angle of 45° on a main surface on the display surface side for one unit panel of the two unit panels are defined as aₓ* and bₓ* at respective angles, and a* and b* for the other unit panel measured in the same manner are defined as a_{y}* and b_{y}* at respective angles, Δa*b* at respective angles is 3.0 or less.

$$Δ {a}^{*} {b}^{*} = {( {( {a}_{x}^{*} - {a}_{y}^{*} )}^{2} + {( {b}_{x}^{*} - {b}_{y}^{*} )}^{2} )}^{1 / 2}$$

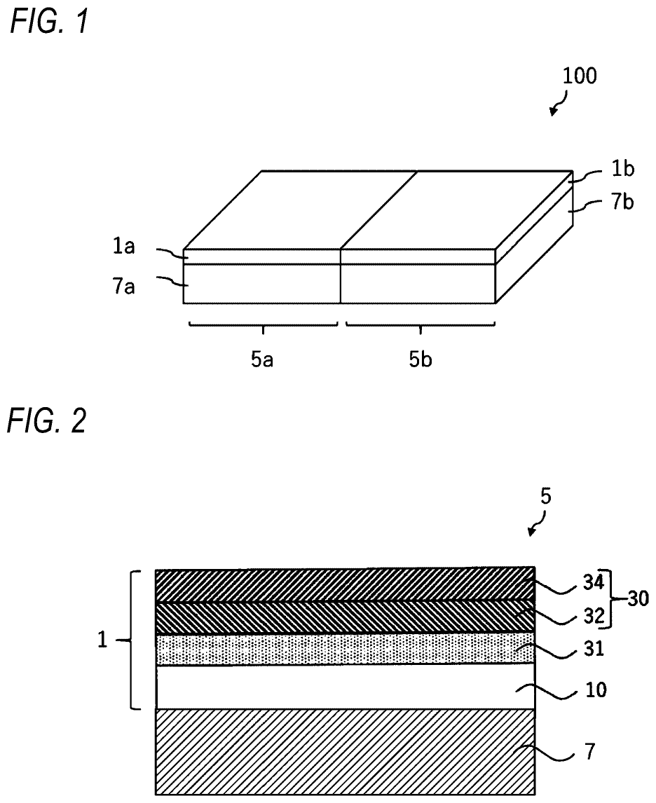

FIG. 1 is a perspective view schematically illustrating an example of the tiling display according to the first embodiment. A tiling display 100 in FIG. 1 includes a unit panel 5a and a unit panel 5b in an array, that is, two unit panels in total. The unit panels 5a and 5b are display panels respectively including at least anti-reflective film-attached transparent substrates 1a and 1b on the display surface side. In FIG. 1, a portion other than the anti-reflective film-attached transparent substrate constituting the display panel, for example, a portion including a display element according to an image display method (display type), is schematically illustrated as main body portions 7a and 7b which form a substantial main body of the display panel. Note that, in the present description, the display surface side refers to a surface on which an image is to be displayed in a tiling display or a unit panel. In FIG. 1 to FIG. 7, a direction toward the top of the paper is the display surface side. In addition, in the present description, the display surface side is sometimes called a front surface side, and the opposite side is sometimes called a back surface side. For the tiling display or the unit panel, “viewed from the front” means that an observer looks perpendicular to the display surface (front surface), and “viewed obliquely” means that the observer looks obliquely to the display surface (front surface).

FIG. 2 is a cross-sectional view schematically illustrating a configuration example of the anti-reflective film-attached transparent substrate in each unit panel. A unit panel 5 shown in FIG. 2 includes an anti-reflective film-attached transparent substrate 1 on the front surface side, and a main body portion 7 on the back surface side. The anti-reflective film-attached transparent substrate 1 includes a transparent substrate 10, a diffusion layer 31, and an anti-reflective film 30 in this order toward the front surface side (display surface side).

In the tiling display according to the first embodiment, two adjacent unit panels satisfy the above condition 1.

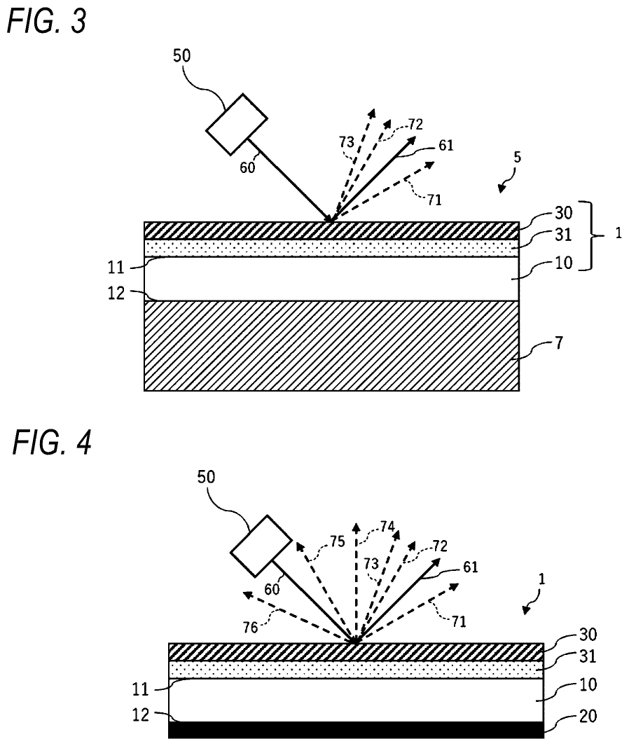

FIG. 3 is a schematic diagram illustrating a method of measuring a* and b* of a diffusely reflected light at each angle according to the condition 1. In the anti-reflective film-attached transparent substrate 1 arranged on the display surface side of the unit panel 5, the transparent substrate 10 has one main surface 11 and the other main surface 12, and the diffusion layer 31 and the anti-reflective film 30 are formed on the one main surface 11, which is a main surface on the display surface side. A light is incident from a light source 50 on the main surface on the display surface side of the unit panel 5, that is, on the one main surface 11 of the anti-reflective film-attached transparent substrate 1, at an incident angle of 45°. The light source used for incidence is one that emits a light over the entire visible light region. As such a light source, for example, a white light source such as a high color rendering white LED is suitably used. With a specularly reflected light 61 of this incident light 60 being taken as a reference (0°), diffusely reflected lights 71, 72, and 73 are diffusely reflected lights at −15°, 15°, and 25°, respectively. Note that, here, with the angle of the specularly reflected light 61 set to 0°, a direction in which the angle increases toward the incident light 60 is set to a +direction, and a direction in which the angle increases toward a side opposite to the incident light 60 is set to a −direction. For these diffusely reflected lights at respective angles, reflectances in a visible light wavelength are measured, and L*, a* and b* under a D65 light source are calculated. The measurement can be performed using, for example, CM-M6 manufactured by Konica Minolta, Inc.

Here, a* and b* of the diffusely reflected lights at respective angles under a D65 light source on the main surface on the display surface side for one unit panel of the two adjacent unit panels are defined as aₓ* and bₓ* at respective angles. That is, aₓ* and bₓ* at −15°, aₓ* and bₓ* at 15°, and aₓ* and bₓ* at 25° on the main surface on the display surface side of the one unit panel are measured. Similarly, a_{y}* and b_{y}* at −15°, a_{y}* and b_{y}* at 15°, and a_{y}* and b_{y}* at 25° are measured for the other unit panel. Then, in the case where Δa*b*'s obtained based on the aₓ “, the bₓ*, the a_{y}”, and the b_{y}* at −15°, the aₓ*, the bₓ*, the a_{y}, and the b_{y}* at 15°, and the aₓ*, the bₓ*, the a_{y}*, and the b_{y}* at 25° are all 3.0 or less, it can be determined that the condition 1 is satisfied.

$$Δ {a}^{*} {b}^{*} = {( {( {a}_{x}^{*} - {a}_{y}^{*} )}^{2} + {( {b}_{x}^{*} - {b}_{y}^{*} )}^{2} )}^{1 / 2}$$

When two adjacent unit panels satisfy the above condition 1, it means that color tones of the diffusely reflected lights at the same angle between the adjacent unit panels are relatively close (a color difference is small). Accordingly, the tiling display according to the first embodiment has a reduced color deviation. That is, in the condition 1, the Δa*b* at each angle is 3.0 or less, preferably 2.5 or less, and more preferably 2.0 or less, from the viewpoint of reducing the color difference of the diffusely reflected lights at each angle.

In the related art, when evaluating the color tone of an object, it is known to evaluate the color tone of a reflected light by using the SCE method. This is a method of evaluating the color tone of an object by eliminating the specularly reflected light and measuring only the diffusely reflected light, among the reflected lights when a light is incident on the object. Evaluating the color tone of the object by using the SCE method can be regarded as evaluating the color tone similar to a color tone when the object is visually observed. However, the inventors of the present invention have found that in the case where color tones evaluated by using the SCE method for two adjacent unit panels are brought closer, the color deviation when viewed from the front tends to be small, but the color deviation when viewed from various angles, such as in an oblique direction, may not be sufficiently reduced. In contrast, according to the present invention, since color tones of diffusely reflected lights at a plurality of angles are adjusted for two adjacent unit panels, the color deviation can be reduced when viewed from various angles, including an oblique direction.

In order to obtain a tiling display satisfying the above requirements for two adjacent unit panels, it is preferable to use the anti-reflective film-attached transparent substrate arranged in each unit panel in which an angle dependency of the diffusely reflected light (change in color tone depending on the angle of the diffusely reflected light) is adjusted to satisfy a predetermined condition. Specific preferred embodiments of the anti-reflective film-attached transparent substrate are to be described later.

### (Unit Panel)

The unit panel is a display panel including at least an anti-reflective film-attached transparent substrate on a display surface side. A plurality of unit panels are arranged to form a tiling display. The unit panel is, for example, a display panel for use in various displays such as a μ-LED display, a liquid crystal display (LCD display), an organic EL display (OLED display), and an electronic paper display, and a specific configuration thereof is not particularly limited and depends on the type or the like of the display. As shown in FIG. 2, the unit panel 5 is, for example, one obtained by arranging the anti-reflective film-attached transparent substrate 1 on the front surface side of the panel-shaped main body portion 7 by means of attaching or the like. In the case of forming the unit panel by attaching the anti-reflective film-attached transparent substrate to the main body portion, an adhesive or the like may be used as appropriate.

The type of the display is not particularly limited and can be appropriately selected depending on the application and the like. For example, although it depends on the application, a μ-LED display can be preferably used. In the case of a μ-LED display, as to be described later, a high definition is likely to be achieved even when a haze of the anti-reflective film-attached transparent substrate is relatively large.

In addition, an LCD display and an OLED display having a relatively small pixel pitch can also be preferably used. In order to achieve a high definition display, in the case where the pixel pitch is relatively small, adjustment may be made to make the haze of the anti-reflective film-attached transparent substrate relatively small.

The size of the main surface per unit panel is not particularly limited, and is, for example, preferably 0.005 m² to 3 m², and more preferably 0.01 m² to 1.5 m², from the viewpoint of a production cost. A single tiling display may include a plurality of types of unit panels having main surfaces having different sizes.

The shape of the main surface of the unit panel is not particularly limited as long as it can be arranged in a tiled manner, and can be appropriately selected from various shapes such as a polygon and a rectangle with rounded corners depending on the application. Typically, a unit panel having a rectangular main surface is preferably used. In addition, the surface of the unit panel may be curved, or the panels may be arranged so as to form a curved surface.

### (Anti-Reflective Film-Attached Transparent Substrate)

The anti-reflective film-attached transparent substrate includes a transparent substrate, a diffusion layer, and an anti-reflective film in this order toward a display surface side. The anti-reflective film-attached transparent substrate 1 illustrated in FIG. 2 is formed with the diffusion layer 31 on the one main surface of the transparent substrate 10 and formed with the anti-reflective film 30 on the diffusion layer 31, and is arranged such that the surface on the anti-reflective film side is the display surface side of the unit panel. Note that, FIG. 2 illustrates a configuration in which the diffusion layer 31 is further formed on the transparent substrate 10. However, as to be described later, the diffusion layer may be formed on a surface layer of the transparent substrate itself by a method such as a surface treatment on the transparent substrate.

In the anti-reflective film-attached transparent substrate, when a light source is incident at an incident angle of 45° on one main surface of the anti-reflective film-attached transparent substrate, the measured a* and b* of diffusely reflected lights at angles of −15°, 15°, 25°, 45°, 75°, and 110° with respect to a specularly reflected light under a D65 light source preferably satisfy at least one of the following conditions A to D.

### (Condition A)

The a* and the b* of the diffusely reflected lights at angles of 15°, 25°, and 45° under a D65 light source satisfy the following formulas (A1) to (A3).

$$( A 1 ) - 8 \leq {a}^{*} \leq 1 \\ ( A 2 ) - 2 \leq {b}^{*} \leq 6 \\ ( A 3 ) {b}^{*} \leq - 1 \times {a}^{*} - 1$$

### (Condition B)

The a* and the b* of the diffusely reflected lights at angles of −15°, 15°, 25°, 45°, 75°, and 110° under a D65 light source satisfy the following formulas (B1) to (B4).

$$( B 1 ) - 6 \leq {a}^{*} \leq 2 \\ ( B 2 ) - 1 \leq {b}^{*} \leq 12 \\ ( B 3 ) {b}^{*} \leq - 2 {a}^{*} + 4 \\ ( B 4 ) {b}^{*} \geq - 2 {a}^{*} - 5$$

### (Condition C)

The a* and the b* of the diffusely reflected lights at angles of −15°, 15°, and 25° under a D65 light source satisfy the following formulas (C1) and (C2).

$$( C 1 ) - 5 \leq {a}^{*} \leq - 1 \\ ( C 2 ) 0 \leq {b}^{*} \leq 9$$

### (Condition D)

An absolute value of a slope of an approximate straight line calculated based on a*b* coordinates of the diffusely reflected lights at angles of −15°, 15°, and 25° under a D65 light source is 2 or more.

FIG. 4 is a diagram schematically illustrating a method of measuring the a* and the b* of the diffusely reflected light at each angle according to the conditions A to D. The measurement of the a* and the b* of the diffusely reflected light at each angle according to the conditions A to D is performed in the same method as in the measurement of the a* and the b* of the diffusely reflected light at each angle according to the condition 1 described above, except that the measurement is performed on the anti-reflective film-attached transparent substrate alone and the diffusely reflected lights at 45°, 75°, and 110° are measured in addition to those at −15°, 15°, and 25°. In FIG. 4, diffusely reflected lights 71, 72, 73, 74, 75 and 76 are diffusely reflected lights at angles of −15°, 15°, 25°, 45°, 75°, and 110°, respectively. Note that, for example, in the case of only determining whether the condition C is satisfied, it is sufficient to measure at least the diffusely reflected lights at −15°, 15°, and 25° required to check the condition, and the same applies to the other condition.

In the case of performing the measurement on the anti-reflective film-attached transparent substrate alone, as shown in FIG. 4, reflection from the other main surface of the anti-reflective film-attached transparent substrate is eliminated during the measurement. In the measurement method illustrated in FIG. 4, the anti-reflective film-attached transparent substrate 1 has a black tape 20 attached to the other main surface 12 to eliminate the reflection on the other main surface. Examples of the black tape used to eliminate the reflection on the other main surface include “KUKKIRI MIERU” manufactured by TOMOEGAWA CORPORATION, and a black tape having a small diffusion reflectance of its own and having little influence on the measurement of the diffusion reflectance of the surface of the transparent substrate having the anti-reflective film can be used.

When the anti-reflective film-attached transparent substrate includes a diffusion layer and an anti-reflective film, in the unit panel or the tiling display, glare from an external light can be prevented, whiteness caused by the diffusely reflected light is prevented, and a black texture is improved. On the other hand, since the anti-reflective film utilizes optical interference, an optical path length changes depending on an incident angle and an emission angle of the light, which may result in various changes in reflection color (color tone). In particular, in the case where the anti-reflective film is provided on the diffusion layer, since the diffusion layer makes it easier for the light to be diffusely reflected, a brightness of the diffusely reflected light tends to be larger, and a change in color tone depending on the angle tends to be more remarkable. In contrast, in an anti-reflective film-attached transparent substrate satisfying at least one of the above conditions A to D, when the angle dependency of the diffusely reflected light is adjusted as follows, the change in color tone depending on the angle is prevented.

That is, in the case of satisfying the condition A, the color tone changes within a limited range between roughly colorless and green, depending on the angle. Accordingly, various changes in color tone depending on the angle are prevented.

In the case of satisfying the condition B, the color tone changes within a limited range between roughly colorless and yellowish green, depending on the angle. Accordingly, various changes in color tone depending on the angle are prevented. In this configuration, in particular, since the reflection color maintains yellowish green while the brightness gradually changes at −15° to 45°, at which the brightness is large, the configuration does not give a particularly strange feeling when visually observed.

In the case of satisfying the condition C, the color tone changes within a limited range between roughly colorless or light yellow and yellowish green, depending on the angle. Accordingly, various changes in color tone depending on the angle are prevented.

In the case of satisfying the condition D, even when the color tone changes depending on the angle, the change in a* is relatively small, and b* mainly changes depending on the angle. With such a change, the change in color tone depending on the angle is likely to be limited, for example, between colorless and a specific color, and various changes in color tone depending on the angle are prevented. Further, this configuration is less likely to cause the reflection color change from green to red, which is likely to give a strange feeling to humans.

Note that, specifically, the approximate straight line related to the condition D is calculated by linear approximation based on the a*b* coordinates of the diffusely reflected light at each angle. That is, the a*b*'s of the diffusely reflected lights at −15°, 15°, and 25° are plotted on an xy coordinate plane (a*b* coordinate plane) with a* as the x-axis and b* as the y-axis, and from the three points, y(b*) is linearly approximated as a linear expression of x(a*) using the least squares method to obtain an approximate straight line. For example, the approximate straight line may be obtained by linear approximation using the “approximate curve” function of spreadsheet software Microsoft Excel (registered trademark) manufactured by Microsoft Corporation.

The reason why the color difference between a plurality of unit panels can be easily reduced by using an anti-reflective film-attached transparent substrate satisfying at least one of the conditions A to D are described below. In order to make the angle dependencies of the diffusely reflected lights the same among a plurality of anti-reflective film-attached transparent substrates, it is conceivable to prepare a plurality of anti-reflective film-attached transparent substrates having the same film configuration of the anti-reflective film. However, even when a plurality of anti-reflective film-attached transparent substrates are produced under the same conditions, it is difficult to make the angle dependencies of the diffusely reflected lights completely the same due to subtle variations in thickness of respective dielectric layers constituting the anti-reflective film. At this time, in the case where the angle dependency of the diffusely reflected light from the anti-reflective film-attached transparent substrate is not appropriately adjusted and the color tone changes variously depending on the angle, even a slight difference in angle dependency can easily result in a large color difference between diffusely reflected lights at the same angle. In contrast, with an anti-reflective film-attached transparent substrate that satisfies at least one of the conditions A to D and that has a limited change in color tone depending on the angle, even when the angle dependency of the diffusely reflected light between a plurality of anti-reflective film-attached transparent substrates is not completely the same, the color tones of the diffusely reflected lights at the same angle tend to be relatively close, making it easier to obtain a combination of a plurality of anti-reflective film-attached transparent substrates that satisfies the above condition 1.

Note that, from the viewpoint of limiting the change in color tone depending on the angle, the anti-reflective film-attached transparent substrate that is likely to have a reduced color difference is not limited to one that satisfies any one of conditions A to D, and may be one in which the change in color tone is adjusted to a limited range in another way. In the case of satisfying any one of the conditions A to D, in addition to limiting the change in color tone, the range in which the color tone changes is preferably between colorless and a specific color, or between similar colors such as light yellow and yellowish green, which is less likely to give a strange feeling to humans.

In order to obtain an anti-reflective film-attached transparent substrate satisfying each of the conditions, it is preferable to appropriately adjust the film configuration of the anti-reflective film and values such as a luminous transmittance (Y) of the anti-reflective film-attached transparent substrate. In the case of an anti-reflective film-attached transparent substrate having a high transmittance, it is difficult to optimize the transmittance, so that it is preferable to more strictly adjust the thickness of each layer of the anti-reflective film.

For example, in the case of obtaining an anti-reflective film-attached transparent substrate satisfying the condition A, a specular reflectance for green light at 500 nm to 550 nm is preferably larger than that for blue light at 450 nm to 500 nm and red light at 600 nm to 650 nm at a plurality of light incident angles. Accordingly, specular reflection colors can be kept from black (colorless) to green at a plurality of light incident angles, and as a result, the diffusion reflection colors at a plurality of incident angles also tend to be kept from colorless to green. An angle dependency of the specular reflection color can be easily predicted by using thin film simulation software. In addition to satisfying (A1) to (A3), it is advantageous in terms of reducing the reflection color deviation to adjust the thickness of each layer such that the change in b* depending on a diffuse reflection angle is reduced.

In the case of obtaining an anti-reflective film-attached transparent substrate satisfying the condition B, the specular reflectance for yellowish green light at about 500 nm to 600 nm is preferably larger than that for blue light at 450 nm to 500 nm and red light at 600 nm to 650 nm at a plurality of light incident angles. Accordingly, specular reflection colors can be kept from black (colorless) to yellowish green at a plurality of light incident angles, and as a result, the diffusion reflection colors at a plurality of incident angles also tend to be kept from black (colorless) to yellowish green.

In the case of an anti-reflective film-attached transparent substrate satisfying the condition C, the specular reflectance for green light at 500 nm to 550 nm is preferably larger than that for blue light at 450 nm to 500 nm and red light at 600 nm to 650 nm at a plurality of light incident angles, and the reflectance for red light is preferably slightly larger than the reflectance for blue light. Accordingly, the reflectance is larger in order in wavelength regions of green, red, and blue, and specular reflection colors can be kept from black (colorless) to yellowish green at a plurality of light incident angles, and as a result, the diffusion reflection colors at a plurality of incident angles also tend to be kept from colorless to light yellowish green. In addition to satisfying (C1) and (C2), it is advantageous in terms of reducing the reflection color deviation to adjust the thickness of each layer such that the change in b* depending on the diffuse reflection angle is reduced.

Examples of a method for obtaining an anti-reflective film-attached transparent substrate satisfying the condition D include adjusting the thickness in the same manner as in the case of the condition C, but the reflection color does not necessarily have to be greenish. For example, reflection of green light at 500 nm to 550 nm is preferably slightly smaller than reflection of blue light at 450 nm to 500 nm and reflection of red light at 600 nm to 650 nm since the reflection color tends to be kept between light reddish blue and light reddish orange.

Further, for example, when the following is satisfied, it tends to be easier to obtain an anti-reflective film-attached transparent substrate satisfying one or more of the conditions A to D.

For example, the anti-reflective film has a total thickness of preferably 200 nm to 250 nm, and more preferably 210 nm to 245 nm. Accordingly, the angle dependency of the diffusion reflection color, that is, an increase in change in color tone of the diffusely reflected light depending on the angle can be prevented, and one or more of the conditions A to D tend to be easily satisfied.

The number of layers in the anti-reflective film is preferably 4 to 8 layers, and more preferably 4 to 6 layers. Accordingly, an increase in angle dependency of the diffusion reflection color can be prevented while ensuring mass productivity, and one or more of the conditions A to D tend to be easily satisfied.

Regarding the thickness of each layer, the thickness of the first high refractive index layer is the most important, and is preferably 1 nm to 25 nm, more preferably 2 nm to 15 nm. Accordingly, the angle dependency of the diffusion reflection color, that is, an increase in change in color tone of the diffusely reflected light depending on the angle can be prevented, and one or more of the conditions A to D tend to be easily satisfied.

In the anti-reflective film-attached transparent substrate, a haze value is preferably 30% or more, more preferably 40% or more, and still more preferably 50% or more, from the viewpoint of suitably preventing the glare. The haze value is preferably, for example, 90% or less, from the viewpoint of improving the clarity of an image when the anti-reflective film-attached transparent substrate is used in an image display device.

In recent years, an anti-reflective film-attached transparent substrate having a relatively large haze value as described above has come to be suitably used for a relatively large display application. The first reason is that when the display is large, the glare from illumination or an external light is more likely to occur, and therefore it is necessary to more suitably prevent the glare. The second reason is that, for example, a large display using a display that tends to have a high definition even when the haze value is relatively large, such as a μ-LED display having a relatively large pixel pitch, is being considered. However, it has been found that, in an anti-reflective film-attached transparent substrate having a relatively large haze value, the amount of diffusely reflected components is larger, so that as the haze increases, the change in color tone depending on the angle of the diffusely reflected light and the color deviation after tiling tend to be particularly remarkable. In contrast, according to the present invention, even when the haze value is relatively large in this way, a tiling display having a suitably reduced color deviation can be obtained.

Note that, in applications such as a LCD display, for example, an anti-reflective film-attached transparent substrate having a haze value of about 0% to 30% may be suitably used. In the present invention, the haze value is not limited to being 30% or less, or less than 30%, depending on the application or the like.

The haze value can be adjusted, for example, according to the surface shape of the diffusion layer. The haze value is measured according to JIS K 7136:2000 using a haze meter (HZ-V3 manufactured by Suga Test Instruments Co., Ltd.) or the like.

### (Brightness L*)

In the anti-reflective film-attached transparent substrate, a brightness L* of the diffusely reflected light at each angle, which is measured in the same method as the a* and the b* of the diffusely reflected light at each angle according to the conditions A to D, is preferably within the following range.

The L* of the diffusely reflected light at −15° under a D65 light source is preferably 30 to 60, and more preferably 40 to 55. When the L* of the diffusely reflected light at −15° is within this range, the anti-reflective film-attached transparent substrate has appropriate light diffusibility (anti-glare properties) or low reflectivity, and can suitably prevent the glare from the external light.

The L* of the diffusely reflected light at 15° under a D65 light source is preferably 15 to 35, and more preferably 20 to 30. When the L* of the diffusely reflected light at 15° is within this range, the anti-reflective film-attached transparent substrate has appropriate light diffusibility (anti-glare properties) or low reflectivity, and can suitably prevent the glare from the external light.

The L* of the diffusely reflected light at 25° under a D65 light source is preferably 5 to 20, and more preferably 7 to 15. When the L* of the diffusely reflected light at 25° is within this range, the anti-reflective film-attached transparent substrate has appropriate light diffusibility (anti-glare properties) or low reflectivity, and can suitably prevent the glare from the external light.

### (Luminous Transmittance: Y)

The anti-reflective film-attached transparent substrate preferably has a luminous transmittance (Y) of 20% to 90%. In the case where the luminous transmittance (Y) is within the above range, the anti-reflective film-attached transparent substrate has an appropriate light absorption ability. Therefore, in the case where the anti-reflective film-attached transparent substrate is used as a cover glass for an image display device, light reflection can be prevented. Accordingly, a bright contrast of the image display device is improved. The luminous transmittance (Y) is more preferably 50% to 90%, and still more preferably 60% to 90%. For example, when it is desired to keep high luminance of a display, an anti-reflective film that does not have a light absorption ability or that has a relatively high transmittance and has a luminous transmittance of 90% or more as an anti-reflective film-attached transparent substrate may be suitably used. In this case, the luminous transmittance (Y) may be 90% to 96%, or is preferably 93% to 96%.

Note that, the luminous transmittance (Y) can be measured according to the method specified in JIS Z 8701 (1999), as to be described later in Examples.

In the anti-reflective film-attached transparent substrate, in order to obtain a luminous transmittance (Y) of 20% to 90%, for example, as a first dielectric layer of the anti-reflective film, it is preferable to mainly use a mixed oxide of an oxide containing at least one selected from a group A consisting of Mo and W and an oxide containing at least one selected from a group B consisting of Si, Nb, Ti, Zr, Ta, Al, Sn, and In, and to adjust an amount of oxidation of the film. In the case of forming an anti-reflective film having a relatively high transmittance and a luminous transmittance of 90% or more as an anti-reflective film-attached transparent substrate, for example, an oxide containing at least one selected from Nb, Ti, Zr, Ta, Al, Sn, Mo, W, and In can be used as the first dielectric layer.

The luminous transmittance (Y) of the anti-reflective film-attached transparent substrate according to the present embodiment can be adjusted, for example, by controlling an irradiation time and an irradiation output of an oxidation source, a distance from the substrate, and an amount of oxidation gas during film-formation of the first dielectric layer in the anti-reflective film, which is a high refractive index layer.

### (Transparent Substrate)

In the present embodiment, the transparent substrate having two main surfaces (hereinafter, also simply referred to as the transparent substrate) preferably has a refractive index of 1.4 or more and 1.7 or less. When the refractive index of the transparent substrate is within the above range, reflection at an adhesion surface can be sufficiently prevented in the case of optically adhering a display, a touch panel, or the like. The refractive index is more preferably 1.45 or more, still more preferably 1.47 or more, and is more preferably 1.65 or less, still more preferably 1.6 or less.

The transparent substrate preferably includes at least one of a glass and a resin. More preferably, the transparent substrate includes both a glass and a resin. When the transparent substrate includes a glass, strength, flatness, and durability of the anti-reflective film-attached transparent substrate can be made excellent. In addition, the diffusion layer can be easily formed by attaching a laminate formed of a resin substrate and a diffusion layer, to be described later, on a glass substrate. In the anti-reflective film-attached transparent substrate on which the diffusion layer is formed by this method, the transparent substrate includes both a glass and a resin.

In the case where the transparent substrate includes a glass, the kind of the glass is not particularly limited, and glasses having various compositions can be used. Among them, the glass preferably contains sodium and preferably has a composition that allows molding and strengthening by a chemical strengthening treatment. Specific examples of the glass include an aluminosilicate glass, a soda lime glass, a borosilicate glass, a lead glass, an alkali barium glass, and an aluminoborosilicate glass.

Note that, in the present description, in the case where the transparent substrate includes a glass, the transparent substrate is also called a glass substrate.

The thickness of the glass substrate is not particularly limited, and in the case of subjecting the glass to a chemical strengthening treatment, the thickness is preferably 5 mm or less, more preferably 3 mm or less, and still more preferably 1.5 mm or less, in order to effectively perform the chemical strengthening. In addition, the thickness is 0.2 mm or more, and preferably 0.2 mm or more and 5 mm or less.

The glass substrate is preferably a chemically strengthened glass obtained by chemical strengthening. Accordingly, the strength of the anti-reflective film-attached transparent substrate is increased. Note that, in the case where the glass substrate is subjected to an anti-glare treatment to be described later, the chemical strengthening is preferably performed after the anti-glare treatment and before forming the anti-reflective film (multilayer film).

In the case where the transparent substrate includes a resin, the kind of the resin is not particularly limited, and resins having various compositions can be used. Among them, the resin is preferably a thermoplastic resin or a thermosetting resin. Examples thereof include a polyvinyl chloride resin, a polyethylene resin, a polypropylene resin, a polystyrene resin, a polyvinyl acetate resin, a polyester resin, a polyurethane resin, a cellulose-based resin, an acrylic resin, an AS (acrylonitrile-styrene) resin, an ABS (acrylonitrile-butadiene-styrene) resin, a fluorine-based resin, a thermoplastic elastomer, a polyamide resin, a polyimide resin, a polyacetal resin, a polycarbonate resin, a modified polyphenylene ether resin, a polyethylene terephthalate resin, a polybutylene terephthalate resin, a polylactic acid-based resin, a cyclic polyolefin resin, and a polyphenylene sulfide resin. Among them, a cellulose-based resin is preferred, and examples thereof include a triacetyl cellulose resin, a polycarbonate resin, and a polyethylene terephthalate resin. These resins may be used alone or in combination of two or more kinds thereof.

The resin particularly preferably includes at least one resin selected from polyethylene terephthalate, a polycarbonate, acrylic, silicone, and triacetyl cellulose, from the viewpoint of excellent visible light transparency and easy availability.

Note that, in the present description, in the case where the transparent substrate includes a resin, the transparent substrate is also called a resin substrate.

The resin substrate is preferably in the form of a film. In the case where the resin substrate is in the form of a film, that is, when it is a resin film, the thickness is not particularly limited, and is preferably 20 μm to 300 μm, and more preferably 30 μm to 130 μm.

Examples of the case where the transparent substrate includes both a glass and a resin include a case of a composite substrate in which a glass substrate and a resin substrate are laminated. More specifically, the transparent substrate may be, for example, in a form in which the above resin substrate is provided on the above glass substrate.

### (Diffusion Layer)

The diffusion layer in the present embodiment is provided on one main surface of the transparent substrate. The diffusion layer refers to a layer having a function of diffusing the specularly reflected light and reducing the glare and the reflection. Examples of the diffusion layer include a diffusion layer imparted with a function of diffusing the specularly reflected light (anti-glare properties) in a hard coat layer and formed of a diffusion layer composition, and a diffusion layer provided with anti-glare properties by a surface treatment or the like on the transparent substrate and formed on a surface layer of the transparent substrate itself. The diffusion layer has an irregular shape on one surface or contains fine particles as a scattering source in the resin, thereby increasing the haze value and imparting anti-glare properties through external scattering or internal scattering. The diffusion layer is formed of a diffusion layer composition obtained by dispersing, in a solution in which a polymer resin as a binder is dissolved, a particulate substance having at least anti-glare properties in itself. The diffusion layer can be formed, for example, by coating one main surface of the transparent substrate with the diffusion layer composition.

Examples of the particulate substance having anti-glare properties include inorganic fine particles such as silica, clay, talc, calcium carbonate, calcium sulfate, barium sulfate, aluminum silicate, titanium oxide, synthetic zeolite, alumina, and smectite, and organic fine particles including a styrene resin, a urethane resin, a benzoguanamine resin, a silicone resin, an acrylic resin, a melamine resin, or the like.

In addition, as the polymer resin as a binder for the diffusion layer, for example, polymer resins such as a polyester-based resin, an acrylic resin, an acrylic urethane-based resin, a polyester acrylate-based resin, a polyurethane-based acrylate resin, an epoxy acrylate-based resin, and a urethane-based resin can be used.

In the present embodiment, the diffusion layer may be formed directly on the transparent substrate, or a laminate formed of a resin substrate and a diffusion layer may be prepared in advance and then attached to a glass substrate or the like to obtain a configuration in which a diffusion layer is provided on a composite substrate of a glass substrate and a resin substrate. Such a laminate is preferably one in which a diffusion layer is formed on a film-like resin substrate. According to this method, the diffusion layer can be formed more easily.

Specific examples of the laminate formed of a resin substrate and a diffusion layer include an anti-glare film, and more specific examples thereof include an anti-glare PET film and an anti-glare TAC film. Examples of the anti-glare PET film include trade name: BHC-III and EHC-30a manufactured by Higashiyama Film Co., Ltd., and those manufactured by REIKO Co., Ltd. As the anti-glare TAC film, an anti-glare TAC film (trade name: VZ50 manufactured by TOPPAN TOMOEGAWA Optical Films Co., Ltd.) or the like is used.

Alternatively, the diffusion layer may be formed on the surface layer of the transparent substrate itself by subjecting the transparent substrate to a surface treatment.

For example, in the case of using a glass substrate, a method of subjecting a main surface of a glass to a surface treatment to form desired irregularities can be used.

Specifically, a method of chemically treating the main surface of the glass substrate, for example, a method of applying a frost treatment, can be used. The frost treatment can be performed, for example, by immersing a glass substrate to be treated in a mixed solution containing hydrogen fluoride and ammonium fluoride, and subjecting the immersed surface to a chemical surface treatment.

In addition to chemical treatment methods such as a frost treatment, for example, a method by a physical treatment can also be used including a so-called sandblast treatment in which a crystalline silicon dioxide powder, a silicon carbide powder, or the like is blown onto the surface of the glass substrate with pressurized air, and polishing with a brush to which a crystalline silicon dioxide powder, a silicon carbide powder or the like adheres is moistened with water.

In the case where one surface of the diffusion layer in an anti-reflective film-attached transparent substrate including such a diffusion layer has an irregular shape, the surface of the anti-reflective film-attached transparent substrate has an irregular shape due to the irregular shape of the diffusion layer. The anti-reflective film-attached transparent substrate has an arithmetic mean surface roughness (Sa) of preferably 0.05 μm to 0.6 μm, and more preferably 0.05 μm to 0.55 μm. The Sa is preferably within this range since it is easier to prevent glare of a reflected image. The Sa is specified in ISO25178, and can be measured, for example, using a laser microscope VK-X3000 manufactured by Keyence Corporation.

In the anti-reflective film-attached transparent substrate, a developed area ratio Sdr (hereinafter, simply referred to as “Sdr”) calculated based on the surface area obtained by measurement using a laser microscope such as VK-X3000 manufactured by Keyence Corporation is preferably 0.001 to 0.4, and more preferably 0.0025 to 0.2. The Sdr is preferably within this range since it is easier to prevent the glare of the reflected image.

The Sdr is specified in ISO25178 and is represented by the following equation.

$$Developed area ratio Sdr = \{ ( A - B ) / B \}$$

A: surface area (developed area) reflecting actual irregularities in measurement region
B: area of flat surface without any irregularities in measurement region

The anti-reflective film-attached transparent substrate has a root mean square slope (Sdq) of preferably 0.03 to 0.50, and more preferably 0.07 to 0.49. The Sdq is preferably within this range since it is easier to prevent the glare of the reflected image. The Sdq is specified in ISO25178, and can be measured, for example, using a laser microscope VK-X3000 manufactured by Keyence Corporation.

The anti-reflective film-attached transparent substrate has an average principal curvature of surface peaks (Spc) of preferably 150 to 6000 (1/mm). The Spc is preferably within this range since it is easier to prevent the glare of the reflected image. The Spc is specified in ISO25178, and can be measured, for example, using a laser microscope VK-X3000 manufactured by Keyence Corporation.

Note that, the above Sa, Sdr, Sdq, and Spc refer to values measured on the main surface of the anti-reflective film-attached transparent substrate on the side where the diffusion layer and the anti-reflective film are provided.

### (Barrier Layer)

The anti-reflective film-attached transparent substrate may include a barrier layer between the transparent substrate and the anti-reflective film. In the case where the transparent substrate includes a resin substrate, such as in the case of forming the diffusion layer by the method of attaching the laminate formed of a resin substrate and a diffusion layer to a glass substrate, a barrier layer may be provided between the diffusion layer and the anti-reflective film. The barrier layer may be preferably provided between the resin transparent substrate and the anti-reflective film, since there are advantages that influences of moisture and oxygen that try to penetrate the anti-reflective film from the resin substrate can be prevented and optical properties are less likely to change. In addition, in the case where the transparent substrate includes a glass substrate, when the barrier layer is provided between the transparent substrate (glass substrate) and the anti-reflective film, alkali metal components and the like can be prevented from diffusing into the anti-reflective film and the change in optical properties can be prevented. Therefore, in the case where the transparent substrate includes a glass substrate, the barrier layer may be provided between the transparent substrate and the anti-reflective film.

Examples of the barrier layer include a metal nitride film and a metal oxide film, specifically, a SiN, film and a SiOₓ film. From the viewpoint of more effectively preventing the change in optical properties, a SiNₓ film is more preferred. That is, the barrier layer preferably includes a layer mainly formed of at least one of SiNₓ and SiOₓ, and more preferably includes a layer mainly formed of SiNₓ. The layer mainly formed of at least one of SiNₓ and SiOₓ means a layer in which a component having the highest content in terms of mass is at least one of SiNₓ and SiOₓ, and is preferably, for example, a layer in which the content of at least one of SiNₓ and SiOₓ is 70 mass % or more. From the viewpoint of preventing moisture from penetrating the anti-reflective film, the thickness of the barrier layer is preferably 2 nm or more, more preferably 4 nm or more, and particularly preferably 8 nm or more. On the other hand, from the viewpoint of preventing an increase in reflectance of the anti-reflective film-attached transparent substrate, the thickness is preferably 50 nm or less. The barrier layer can be formed by using, for example, a known film-forming method such as a sputtering method, a vacuum deposition method, or a coating method.

### (Anti-Reflective Film)

The anti-reflective film in the present embodiment has a function of preventing the light reflection, and has a laminated structure in which at least two dielectric layers having different refractive indices are laminated.

The anti-reflective film (multilayer film) 30 shown in FIG. 2 has a laminated structure including two layers in which a first dielectric layer 32 and a second dielectric layer 34 having different refractive indices are laminated. When the first dielectric layer 32 and second dielectric layer 34 having different refractive indices are laminated, the light reflection can be prevented. For example, in FIG. 2, the first dielectric layer 32 is a high refractive index layer and the second dielectric layer 34 is a low refractive index layer.

It is preferable that the anti-reflective film have a laminated structure in which at least two dielectric layers having different refractive indices are laminated, at least one of the dielectric layers be mainly formed of a Si oxide, at least another layer among layers in the laminated structure be mainly formed of a mixed oxide of an oxide containing at least one selected from the group A consisting of Mo and W and an oxide containing at least one selected from the group B consisting of Si, Nb, Ti, Zr, Ta, Al, Sn, and In, and a content of elements of the group B contained in the mixed oxide be 65 mass % or less with respect to a total of elements of the group A contained in the mixed oxide and the elements of the group B contained in the mixed oxide. When it is desired to keep high luminance of a display, in the case where an anti-reflective film that does not have a light absorption ability or that has a relatively high transmittance and has a luminous transmittance of 90% or more as an anti-reflective film-attached transparent substrate is suitably used, an oxide containing at least one selected from the group consisting of Nb, Ti, Zr, Ta, Al, Sn, Mo, W, and In may be used as a layer not formed of a Si oxide. The layer mainly formed of a Si oxide may contain an oxide containing at least one selected from Nb, Ti, Zr, Ta, Al, Sn, W, Mo, and In in a range that the reflectance is not influenced. By appropriately selecting the oxide material, it is possible to obtain an anti-reflective film that has high hardness and that exhibits little change in optical properties.

In the anti-reflective film (multilayer film) 30 shown in FIG. 2, in the case of obtaining an anti-reflective film having a luminous transmittance of 90% or less as an anti-reflective film-attached transparent substrate, the first dielectric layer (high refractive index layer) 32 is preferably mainly formed of a mixed oxide of an oxide containing at least one selected from the group A consisting of Mo and W and an oxide containing at least one selected from the group B consisting of Si, Nb, Ti, Zr, Ta, Al, Sn, and In. In the mixed oxide, a content of elements of the group B contained in the mixed oxide (hereinafter, referred to as a group B content) is preferably 65 mass % or less with respect to a total of elements of the group A contained in the mixed oxide and the elements of the group B contained in the mixed oxide. Here, “mainly” means a component that is contained in the largest amount (in terms of mass) in the first dielectric layer 32, and means that the first dielectric layer 32 contains, for example, 70 mass % or more of the component.

When the group B content in the first dielectric layer (A-B-O) 32, which is formed of the mixed oxide of an oxide containing at least one selected from the group A consisting of Mo and W and an oxide containing at least one selected from the group B consisting of Si, Nb, Ti, Zr, Ta, Al, Sn, and In, is 65 mass % or less, it is possible to prevent the transmitted light from being yellowish.

The oxide containing at least one selected from the group A is preferably Mo, or Mo and W, and the oxide containing at least one selected from the group B is preferably Nb. That is, the first dielectric layer is preferably a mixed oxide containing Mo and Nb or a mixed oxide containing Mo, W, and Nb, and more preferably a mixed oxide containing Mo, W, and Nb.

As to be described later, the second dielectric layer may be, for example, an oxygen-deficient silicon oxide layer. Here, the oxygen-deficient silicon oxide layer in the related art is yellowish when exposed to a visible light. However, the first dielectric layer is preferably made of a mixed oxide containing Mo and Nb or a mixed oxide containing Mo, W and Nb, since this can prevent the silicon oxide layer from being yellowish. In addition, for the purpose of improving reliability, the silicon oxide layer may contain an oxide containing at least one selected from the group consisting of Nb, Ti, Zr, Ta, Al, Sn, W, Mo, and In, and each oxide may have oxygen deficiency. Further, in the case of forming the second dielectric layer on the diffusion layer having a relatively high haze as described above, that is, relatively large surface irregularities, high oxidation stability is required during the film formation. The first dielectric layer is more preferably a mixed oxide containing Mo, W and Nb since this tends to provide excellent oxidation stability during the film formation.

The first dielectric layer 32 has a refractive index at a wavelength of 550 nm of preferably 1.8 to 2.5 from the viewpoint of a transmittance with the transparent substrate.

The first dielectric layer 32 has an extinction coefficient of preferably 0.005 to 3, and more preferably 0.04 to 0.38. When the extinction coefficient is 0.005 or more, a desired absorption rate can be achieved with an appropriate number of layers. In addition, when the extinction coefficient is 3 or less, it is relatively easy to achieve both the reflection color tone and the transmittance.

The second dielectric layer 34 (low refractive index layer) is preferably mainly formed of a Si oxide (SiOₓ). Here, “mainly” means a component that is contained in the largest amount (in terms of mass) in the second dielectric layer 34, and means that the second dielectric layer 34 contains, for example, 70 mass % or more of the component. The second dielectric layer 34 (low refractive index layer) is preferably mainly formed of a Si oxide (SiOₓ) since the refractive index is low and a reflectance reduction effect is high. Note that, SiOₓ may be fully oxidized silicon oxide (SiO₂), but from the viewpoint of improving optical reliability and scratch resistance, SiOₓ is preferably an oxygen-deficient silicon oxide. In addition, for the purpose of improving reliability, the silicon oxide layer may contain an oxide containing at least one selected from the group consisting of Nb, Ti, Zr, Ta, Al, Sn, W, Mo, and In, and each oxide may have oxygen deficiency.

The anti-reflective film (multilayer film) 30 shown in FIG. 2 has a two-layer laminated structure in which the first dielectric layer 32 and the second dielectric layer 34 are laminated. The anti-reflective film (multilayer film) in the present embodiment is not limited to this, and may have a laminated structure in which three or more dielectric layers having different refractive indices are laminated. In this case, it is not necessary for all dielectric layers to have different refractive indices. For example, in the case of a three-layer laminated structure, it can be a three-layer laminated structure including a low refractive index layer, a high refractive index layer, and a low refractive index layer, or a three-layer laminated structure including a high refractive index layer, a low refractive index layer, and a high refractive index layer. In the former case, the two low refractive index layers may have the same refractive index, and in the latter case, the two high refractive index layers may have the same refractive index. In the case of a four-layer laminated structure, it can be a four-layer laminated structure including a low refractive index layer, a high refractive index layer, a low refractive index layer, and a high refractive index layer, or a four-layer laminated structure including a high refractive index layer, a low refractive index layer, a high refractive index layer, and a low refractive index layer. In this case, at least one of the two low refractive index layers and the two high refractive index layers may have the same refractive index.

In the case of a laminated structure in which three or more layers having different refractive indices are laminated, a dielectric layer other than the first dielectric layer (A-B-O) 32 and the second dielectric layer (SiOₓ) 34 may be included. In this case, each layer is selected to form a three-layer laminated structure including a low refractive index layer, a high refractive index layer, and a low refractive index layer, or a three-layer laminated structure including a high refractive index layer, a low refractive index layer, and a high refractive index layer, or a four-layer laminated structure including a low refractive index layer, a high refractive index layer, a low refractive index layer, and a high refractive index layer, or a four-layer laminated structure including a high refractive index layer, a low refractive index layer, a high refractive index layer, and a low refractive index layer, each laminated structure including the first dielectric layer (A-B-O) 32 and the second dielectric layer (SiOₓ) 34.

The outermost layer is preferably the second dielectric layer (SiOₓ) 34. When the outermost layer is the second dielectric layer (SiOₓ) in order to obtain low reflectivity, production is relatively easy. In addition, although the reflectance may increase slightly, for the purpose of improving the reliability, the second dielectric layer may contain an oxide containing at least one selected from the group consisting of Nb, Ti, Zr, Ta, Al, Sn, W, Mo, and In. In order to prevent the increase in reflectance, the content of metals other than Si, excluding oxygen, is preferably 30 at % or less, more preferably 20 at % or less, and still more preferably 15 at % or less. In addition, in the case of forming an antifouling film to be described later on the anti-reflective film 30, it is preferable to form the antifouling film on the second dielectric layer (SiOₓ) from the viewpoint of bonding properties related to the durability of the antifouling film.

The first dielectric layer (A-B-O) 32 is preferably amorphous. Being amorphous, it can be produced at a relatively low temperature, and is suitable for use in the case where the transparent substrate includes a resin, since the resin is not damaged by heat.

The anti-reflective film 30 in the present embodiment can be formed on the main surface of the transparent substrate using a known film-forming method such as a sputtering method, a vacuum deposition method, or a coating method. That is, the dielectric layers constituting the anti-reflective film 30 are formed on the main surface of the diffusion layer 31, according to the lamination order, using a known film-forming method such as a sputtering method, a vacuum deposition method, or a coating method.

Examples of the sputtering method include methods such as magnetron sputtering, pulse sputtering, AC sputtering, and digital sputtering.

For example, the magnetron sputtering method is a method in which a magnet is placed on a back surface of a base dielectric material to generate a magnetic field, and gas ion atoms collide with the surface of the dielectric material and are ejected, to form a sputtering film having a thickness of several nm, and a continuous film of a dielectric that is an oxide or a nitride of the dielectric material can be formed.

In addition, for example, the digital sputtering method is a method of forming a metal oxide thin film by repeating steps of first forming a metal ultra-thin film by sputtering, and then oxidizing the film by irradiation with oxygen plasma, oxygen ions, or oxygen radicals in the same chamber, unlike a general magnetron sputtering method. In this case, since film-forming molecules are metals when deposited on a substrate, it is presumed to be more ductile than a case of depositing a metal oxide. Therefore, it is conceivable that even when the energy is the same, rearrangement of the film-forming molecules is likely to occur, and as a result, a dense and smooth film can be formed.

Note that, an example of a preferred configuration of the anti-reflective film has been given above, but the configuration of the anti-reflective film is not limited to this. For example, when it is desired to keep high luminance of a display, an anti-reflective film that does not have a light absorption ability or that has a relatively high transmittance and has a luminous transmittance of 90% or more as an anti-reflective film-attached transparent substrate may be suitably used. In such an anti-reflective film-attached transparent substrate including an anti-reflective film having a high transmittance, the effect of reducing the color deviation after tiling can also be obtained so long as the a* and the b* of the diffusely reflected light at each angle are within the above ranges. Examples of a configuration including the anti-reflective film having a high transmittance include a configuration in which a low refractive index layer is similar to the above second dielectric layer 34, while a high refractive index layer is a layer that does not have a light absorption ability or that has a high transmittance. Examples of the high refractive index layer in this case include a layer mainly formed of a Ti oxide (TiOₓ), a layer formed of a Nb oxide (NbOₓ), and a layer formed of a Ta oxide (TaOₓ), and a layer mainly formed of an oxide of Ti (TiOₓ) is preferred from the viewpoint of reducing the reflectance. In this case, each layer constituting the anti-reflective film can also be formed using a known film-forming method such as a sputtering method, a vacuum deposition method, or a coating method.

The luminous transmittance (Y) of the anti-reflective film-attached transparent substrate in the case of including the anti-reflective film having a high having a high transmittance may be, for example, 90% to 96%, and is preferably 93% to 96%.

### (Antifouling Film)

The anti-reflective film-attached transparent substrate according to the present embodiment may further include an antifouling film (also referred to as an “anti finger print (AFP) film”) on the anti-reflective film, from the viewpoint of protecting the outermost surface of the anti-reflective film. The antifouling film can be formed of, for example, a fluorine-containing organosilicon compound. The fluorine-containing organosilicon compound is not particularly limited as long as it can impart an antifouling property, water repellency, and oil repellency, and examples thereof include a fluorine-containing organosilicon compound having one or more groups selected from the group consisting of a polyfluoropolyether group, a polyfluoroalkylene group, and a polyfluoroalkyl group. Note that, the polyfluoropolyether group is a divalent group having a structure in which polyfluoroalkylene groups and etheric oxygen atoms are alternately bonded.

As a commercially available fluorine-containing organosilicon compound having one or more groups selected from the group consisting of a polyfluoropolyether group, a polyfluoroalkylene group, and a polyfluoroalkyl group, KP-801 (trade name, manufactured by Shin-Etsu Chemical Co., Ltd.), KY178 (trade name, manufactured by Shin-Etsu Chemical Co., Ltd.), KY-130 (trade name, manufactured by Shin-Etsu Chemical Co., Ltd.), KY-185 (trade name, manufactured by Shin-Etsu Chemical Co., Ltd.), and Optool (registered trademark) DSX and Optool AES (trade name, all manufactured by Daikin Industries, Ltd.) can be preferably used.

In the case where the anti-reflective film-attached transparent substrate according to the present embodiment includes an antifouling film, the antifouling film is provided on the anti-reflective film. In the case where the anti-reflective film is provided on both main surfaces of the transparent substrate, the antifouling film can be formed on both the anti-reflective films, or the antifouling film may be laminated on only one of the main surfaces. This is because the antifouling film only needs to be provided at places where there is a possibility of contact with human hands, and the configuration can be selected according to the application.

### (Method for Producing Anti-Reflective Film-Attached Transparent Substrate)

A method for producing an anti-reflective film-attached transparent substrate is not particularly limited, and for example, the anti-reflective film-attached transparent substrate can be produced by a method including forming a diffusion layer and an anti-reflective film in this order on a transparent substrate. If necessary, the method may further include forming a layer such as a barrier layer or an antifouling film.

### (Configuration of Tiling Display)

The number of unit panels constituting the tiling display is not particularly limited as long as it is at least two. Although it depends on the size of the unit panel and the size of a desired tiling display, for example, the number of unit panels is preferably 2 to 1000, and more preferably 4 to 500, from the viewpoint of achieving a large screen.

The size of the tiling display, that is, an area of a image display surface of the tiling display is not particularly limited depending on the application or the like, and from the viewpoint of achieving a large screen, for example, it is preferably 1.5 m² to 150 m², and more preferably 2 m² to 100 m².

The tiling display may be the tiling display according to the first embodiment, and may also be a tiling display according to a second embodiment to be described later. In this case, in the tiling display according to the first embodiment, the anti-reflective film-attached transparent substrate includes an anti-glare film as the diffusion layer and the transparent substrate, and two adjacent unit panels satisfy a condition 2 to be described later.

Note that, the anti-reflective film-attached transparent substrate including an anti-glare film as the diffusion layer and the transparent substrate means that the anti-reflective film-attached transparent substrate includes an anti-glare film, a diffusion layer of the anti-glare film constitutes the diffusion layer of the anti-reflective film-attached transparent substrate, and a resin substrate of the anti-glare film constitutes a part or all of the transparent substrate of the anti-reflective film-attached transparent substrate. The anti-glare film and the condition 2 in the second embodiment are to be described in detail later.

### (Method for Producing Tiling Display)

A method for producing a tiling display according to the first embodiment of the present invention is a method for producing a tiling display obtained by arranging a plurality of unit panels, each including an anti-reflective film-attached transparent substrate on a display surface side, and the method includes: determining a* and b* of diffusely reflected lights at angles of −15°, 15°, and 25° with respect to a specularly reflected light under a D65 light source when a light source is incident at an incident angle of 45° on a main surface on the display surface side for the plurality of unit panels (step A11); and selecting a combination of unit panels that satisfies the above condition 1, and arranging the unit panels corresponding to the combination adjacent to each other (step A12).

When unit panels in a combination that satisfies the above condition 1 are arranged adjacent to each other in the tiling display, a color difference of diffusely reflected lights at a plurality of angles between these unit panels is relatively small, and a color deviation is reduced.

In the step A11, a and b* of diffusely reflected lights at angles of −15°, 15°, and 25° with respect to a specularly reflected light under a D65 light source when a light source is incident at an incident angle of 45° on the main surface on the display surface side of the plurality of unit panels are determined. The method of measuring the a* and the b* of the diffusely reflected light at each angle is the same as the method of measuring the a* and the b* of the diffusely reflected light at each angle under a D65 light source according to the above condition 1. The method of determining the a* and the b* of the diffusely reflected light at each angle may be a method of checking measured values that have been measured and recorded in advance, or a method of measuring and determining the a* and the b* each time. Since the color tone of an object may change over time, in the case where a change in color tone is suspected due to a long period of time having passed since the last measurement, it is more preferable to measure again and determine the a* and the b* of the diffusely reflected light at each angle.

The plurality of unit panels to be measured are not particularly limited, and for example, it is preferable to produce a plurality of anti-reflective film-attached transparent substrates satisfying at least one or more of the above conditions A to D under the same conditions, and to measure a plurality of unit panels in which the plurality of anti-reflective film-attached transparent substrates are arranged on display surface sides. Accordingly, it is easier to select a combination of unit panels that satisfies the condition 1 from among the plurality of unit panels.

In the step A12, a combination of unit panels that satisfies the above condition 1 is selected, and unit panels corresponding to the combination are arranged adjacent to each other. The selection may be made based on the determination result in the step A11.

When the number of the unit panels constituting the tiling display is three or more, it is more preferable to arrange the unit panels such that in the obtained tiling display, all combinations of two adjacent unit panels are the combination of unit panels satisfying the condition 1. A specific procedure for selecting the combination and arranging the unit panels is not particularly limited. When a unit panel group is selected such that any two unit panels selected from a plurality of unit panels satisfy the condition 1, since the two adjacent unit panels satisfy the condition 1 no matter how the unit panels belonging to the unit panel group are arranged, the arrangement can be easily performed, which is preferred.

A specific method of arranging a plurality of unit panels to form a tiling display is not particularly limited, and any method known in the art for tiling displays can be used. Examples thereof include a method of directly connecting unit panels by providing each unit panel with a member for connecting to an adjacent unit panel as connection means, and a method of indirectly connecting unit panels by providing an auxiliary member on a back surface side of the tiling display and arranging a plurality of unit panels on the auxiliary member. Note that, it is not essential that the unit panels are physically connected to each other, and as long as a plurality of unit panels are arranged in a tiled manner, this can be considered a tiling display.

### (Unit Panel Group)

A unit panel group according to the first embodiment of the present invention is a unit panel group for use in a tiling display obtained by arranging a plurality of unit panels, each including an anti-reflective film-attached transparent substrate on a display surface side, in which the anti-reflective film-attached transparent substrate includes a transparent substrate, a diffusion layer, and an anti-reflective film in this order toward the display surface side, and any two unit panels selected from the unit panel group satisfy the above condition 1.

With the unit panel group according to the first embodiment of the present invention, when a plurality of unit panels are arranged to form a tiling display, any two adjacent unit panels satisfy the condition 1 no matter how unit panels belonging to the unit panel group are arranged.

Accordingly, the tiling display according to the first embodiment of the present invention described above can be easily obtained.

Note that, preferred embodiments of each unit panel constituting the unit panel group are similar to those of the unit panel used in the above first embodiment. For example, the haze value of the anti-reflective film-attached transparent substrate provided in each unit panel in the unit panel group is preferably 30% or more.

### (Method for Maintaining Tiling Display)

A method for maintaining a tiling display according to the first embodiment of the present invention is a method for maintaining a tiling display obtained by arranging a plurality of unit panels, each including an anti-reflective film-attached transparent substrate on a display surface side, and the method includes: selecting a unit panel to be replaced from the unit panels constituting the tiling display (step B11); determining a* and b* of diffusely reflected lights at angles of −15°, 15°, and 25° with respect to a specularly reflected light under a D65 light source when a light source is incident at an incident angle of 45° on a main surface on the display surface side for at least one adjacent unit panel adjacent to the unit panel to be replaced (step B12); and replacing the unit panel to be replaced such that a unit panel after replacement and the adjacent unit panel satisfy the following condition 1 (step B13).

In the step B11, a unit panel to be replaced is selected from the unit panels constituting the tiling display. For example, a faulty unit panel or a damaged unit panel can be replaced. In addition, a unit panel that operates normally may also be replaced. For example, a predetermined selection criterion may be set for the purpose of preventing failure, and a unit panel satisfying the criterion may be replaced. The unit panel to be replaced may be one or more.

In the step B12, a* and b* of diffusely reflected lights at angles of −15°, 15°, and 25° with respect to a specularly reflected light under a D65 light source when a light source is incident at an incident angle of 45° on the main surface on the display surface side for at least one adjacent unit panel adjacent to the unit panel to be replaced are determined. The step B12 is similar to the above step A11, except that the determination target is the a* and the b* of the diffusely reflected light at each angle on the adjacent unit panel. The method of determining the a* and b* may be a method of determining information (measured values or the like) that has been measured and recorded in advance, or a method of measuring and determining the a* and b* each time.

In the step B13, the unit panel to be replaced is replaced such that a unit panel after replacement and the adjacent unit panel satisfy the following condition 1. The “replacement” as used herein includes replacement of a whole unit panel with another unit panel, and replacement of a part of a unit panel, such as replacement of only the anti-reflective film-attached transparent substrate in the unit panel. It is preferable to select an appropriate unit panel or anti-reflective film-attached transparent substrate based on the determination result in the step B12 and replace the unit panel or the anti-reflective film-attached transparent substrate.

With the method for maintaining a tiling display according to the first embodiment of the present invention, when replacing some of unit panels in a tiling display, a color deviation in the tiling display after replacement can be reduced.

Note that, in the case where there are a plurality of unit panels adjacent to one unit panel to be replaced, by performing the step B12 and the step B13 on at least one of the adjacent unit panels, the color difference between the adjacent unit panel and the unit panel after replacement is reduced. It is more preferable to perform the step B12 and the step B13 on all of the adjacent unit panels, since this reduces the color differences between all of the adjacent unit panels and the unit panel after replacement.

### Second Embodiment

### (Tiling Display)

A tiling display according to the second embodiment of the present invention is a tiling display obtained by arranging a plurality of unit panels, each including an anti-glare film on a display surface side, in which two of the unit panels adjacent to each other satisfy the following condition 2.

### (Condition 2)

A difference between an angle in a direction where an L* value is maximum for one unit panel of the two adjacent unit panels and an angle in a direction where an L* value is maximum for the other unit panel measured in the same manner is 35° or less, as obtained by the following method.

### (Method)

In a plane parallel to a main surface of the tiling display, one direction of directions parallel to a side shared by the two adjacent unit panels is defined as a 0° direction. A light source is incident on a main surface on the display surface side of a unit panel to be measured at an incident angle of 45° while changing an incident direction from the 0° direction to a 360° direction at an interval of 10°. An L* value of a diffusely reflected light at an angle of −15° with respect to a specularly reflected light of an incident light under a D65 light source is measured at each incident direction, and an angle in the incident direction where the L* value is maximum is defined as the angle in the direction where the L* value is maximum for the unit panel to be measured.

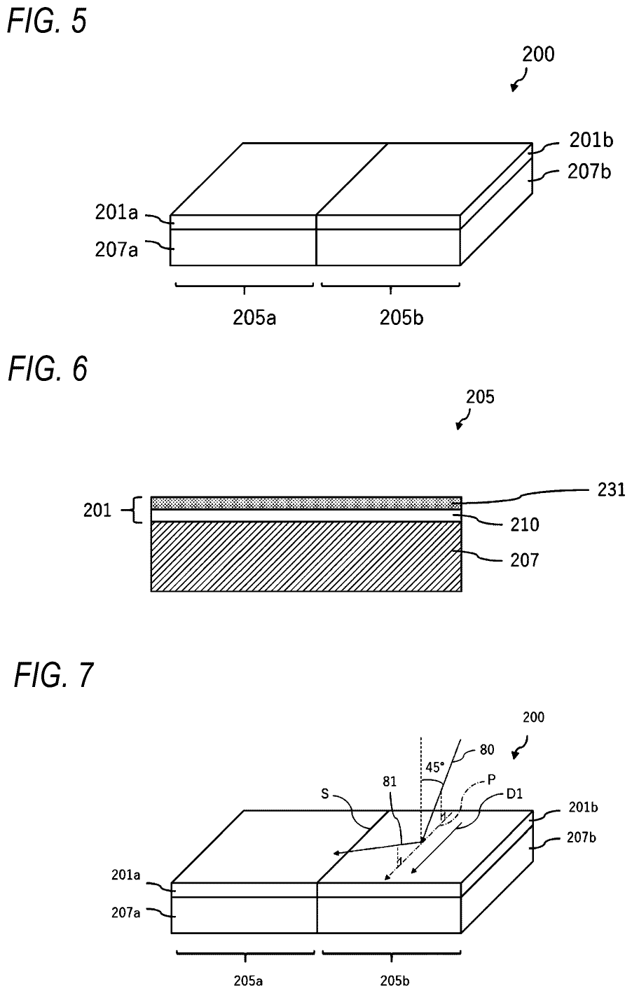

FIG. 5 is a perspective view schematically illustrating an example of the tiling display according to the second embodiment. A tiling display 200 in FIG. 5 includes a unit panel 205a and a unit panel 205b in an array, that is, two unit panels in total. The unit panels 205a and 205b are display panels respectively including at least anti-glare films 201a and 201b on the display surface side. In FIG. 5, a portion other than the anti-glare film constituting the display panel, for example, a portion including a display element according to an image display method (display type), is schematically illustrated as main body portions 207a and 207b which form a substantial main body of the display panel.

FIG. 6 is a cross-sectional view schematically illustrating a configuration example of the anti-glare film in each unit panel. A unit panel 205 shown in FIG. 6 includes an anti-glare film 201 on the front surface side, and a main body portion 207 on the back surface side. The anti-glare film 201 includes a resin substrate 210 and a diffusion layer 231 formed on the resin substrate 210.

In the tiling display according to the second embodiment, two adjacent unit panels satisfy the above condition 2.

Here, the angle in the direction where the L* value is maximum according to the condition 2 is measured by using the above method, and more specifically, is as follows.

FIG. 7 is a diagram illustrating a method of measuring the angle in the direction where the L* value is maximum for the two adjacent unit panels 205a and 205b in the tiling display 200. More specifically, FIG. 7 is a diagram schematically showing a case of measuring the L* value of a diffusely reflected light at −15° for the unit panel 205b when the incident direction is the 0° direction.

In the measurement, first, in a plane parallel to a main surface of the tiling display, one direction of directions parallel to a side shared by two adjacent unit panels is defined as a 0° direction. That is, in FIG. 7, among directions parallel to a side S shared by the unit panel 205a and the unit panel 205b when the tiling display is viewed from the front, a direction toward the front in FIG. 7 is defined as a 0° direction D1. Any direction parallel to the side shared by two adjacent unit panels may be defined as the 0° direction. In the case where two adjacent unit panels do not share a straight side, any one direction on the main surface of the tiling display is defined as the 0° direction. In addition, 0° to 360° directions are defined as angles increasing in the clockwise direction when the tiling display is viewed from the front. The 0° direction and the 360° direction are the same direction. A light source is incident on a main surface on a display surface side of a unit panel to be measured at an incident angle of 45° while changing an incident direction from the 0° direction to the 360° direction at an interval of 10°. For example, as shown in FIG. 7, when trajectories of an incident light 80 and a diffusely reflected light 81 are projected onto a plane parallel to the main surface of the tiling display, in the case where a traveling direction of the light on a projection trajectory P is the 0° direction, it can be defined that the light source is incident with the incident direction being the 0° direction. Then, the L* value of the diffusely reflected light at an angle of −15° with respect to the specularly reflected light of the incident light under a D65 light source is measured at each incident direction. That is, the L* value is measured in a total of 36 directions for each unit panel, i.e., the L* value in the case where the incident direction is the 0° direction, the L* value in the case where the incident direction is a 10° direction, . . . , and the L* value in the case where the incident direction is the 360° direction. Then, the angle in the incident direction where the L* value is maximum among the 36 directions is defined as the angle in the direction where the L* value is maximum for the unit panel to be measured. Here, the diffusely reflected light at an angle of −15° with respect to the specularly reflected light of the incident light is the same as the diffusely reflected light at −15° according to the condition 1 in the first embodiment described above. The measurement according to the condition 2 can be performed using, for example, CM-M6 manufactured by Konica Minolta, Inc. The light source and measurement conditions used in the measurement can be the same as those in the measurement according to the condition 1.

The above measurement is performed for each of two adjacent unit panels, and the angles in the direction where the L* value is maximum are compared to determine whether the condition 2 is satisfied. For the difference between the angles in the direction where the L* value is maximum, substantial closeness of the two angles in the direction is evaluated. That is, the difference is 0° or more and 180° or less. For example, when the angles in the direction where the L* value is maximum are 10° and 350° for two unit panels, the difference therebetween is 20°.

The magnitude of the L* value being different depending on a direction on a measurement surface means that the degree of the light diffusibility is different depending on the direction on the measurement surface, that is, depending on a direction from which the measurement surface is viewed. A large L* value at −15° means that the anti-glare film has a large diffusion reflectance, which means that the light diffusibility is higher. In the anti-glare film, generally, the diffusion reflectance in a direction parallel to a machine direction (MD) during production is larger than the diffusion reflectance in a width direction (TD), and among directions on the surface of the anti-glare film, the diffusion reflectance in one of the directions parallel to the MD tends to be almost maximum, while the diffusion reflectance in one of the directions parallel to the TD tends to be almost minimum. Therefore, when two adjacent unit panels satisfy the above condition 2, it means that the directions of the anti-glare films in the two unit panels during production are aligned with each other on the main surface of the tiling display, or are arranged with a relatively small slope. In other words, it means that orientations of anti-glare films in adjacent unit panels on the tiling display are relatively consistent. Accordingly, it is conceivable that this can reduce a variation in the way the light diffusibility changes between adjacent unit panels when the tiling display is viewed from various directions, and the color deviation between unit panels is less noticeable. Note that, as described above regarding the SCE method, it is known that the color tone of an object can be evaluated by measuring the diffusely reflected light. Therefore, in the second embodiment, it is conceivable that reducing a variation in L* of the diffusely reflected light between unit panels ultimately contributes to reducing the color deviation.

From the viewpoint of more suitably obtain the above effect, in the condition 2, the difference between the angles in the direction where the L* value is maximum is 35° or less, preferably 30° or less, and more preferably 25° or less. The difference between the angles in the directions where the L* value is maximum may be 0°.

The method for obtaining a tiling display satisfying the condition 2 is not particularly limited, and examples thereof include a method of preparing a plurality of unit panels obtained by arranging (attaching) anti-glare films such that any one direction on the anti-glare film (for example, one of the directions parallel to the MD) is parallel to any one direction on the main surface of the unit panel (for example, the longitudinal direction), and arranging the unit panels. That is, it is preferable to prepare and arrange unit panels such that the directions of the anti-glare films in adjacent unit panels during production are aligned with each other on the main surface of the tiling display, or the slope is relatively small. Note that, here, the “parallel” means that an inclination angle with respect to a reference line is, for example, 30° or less.

A difference between the maximum L* values of two adjacent unit panels measured at an interval of 10° by the above method is preferably 3 or less, more preferably 2 or less, and still more preferably 1 or less. In the case where the difference between the maximum values of two adjacent unit panels is relatively small, it is conceivable that the anti-glare properties of the two adjacent unit panels are equal in magnitude. Accordingly, not only a variation in anti-glare properties between unit panels due to differences in diffusion reflection depending on the direction (directivity) on the anti-glare film is reduced, but also a variation due to the difference in anti-glare properties between unit panels is reduced, thereby more effectively reducing the color deviation. For example, in a plurality of anti-glare film-attached transparent substrates obtained from anti-glare films produced under the same production conditions and unit panels including the same, the difference between the maximum values is generally fall within the above range.

### (Unit Panel)

The unit panel is a display panel including at least an anti-glare film on a display surface side. The unit panel in the second embodiment is similar to the unit panel in the first embodiment, except that an anti-glare film is provided on the display surface side of the unit panel instead of the anti-reflective film-attached transparent substrate. Note that, as to be described later, the anti-glare film may be an anti-reflective film-attached transparent substrate further including an anti-reflective film on the anti-glare film. In addition, an anti-glare film-attached transparent substrate having an anti-glare film attached on a transparent substrate may be disposed on the display surface side of the unit panel.

### (Anti-Glare Film)

The anti-glare film includes a resin substrate and a diffusion layer formed on the resin substrate. The diffusion layer is formed by forming a layer having an irregular shape on the surface or by applying a resin having fine particles mixed therein, thereby increasing the haze and imparting anti-glare properties. As described above, generally, since in the anti-glare film, the diffusion reflectance in the machine direction (MD) during production is larger than the diffusion reflectance in the width direction (TD), among directions on the surface of the anti-glare film, the L* value in one of the directions parallel to the MD tends to be almost maximum, while the L* value in one of the directions parallel to the TD tends to be almost minimum. Such a difference in L* values are conceivable to arise from a difference in tension between the MD and the TD when the resin substrate of the anti-glare film is coated with an anti-glare liquid using a roll to roll method. Therefore, as the anti-glare film for use in the second embodiment, a film obtained by wet-coating the resin substrate of the anti-glare film with an anti-glare liquid using a roll to roll method can be suitably used. As long as the anti-glare film has a similar directivity for the L* value at −15°, the embodiment of the anti-glare film is not limited to the above.

The material of the resin substrate of the anti-glare film is not particularly limited, and for example, a thermoplastic resin or a thermosetting resin can be used. Examples of the thermoplastic resin or the thermosetting resin include a polyvinyl chloride resin, a polyethylene resin, a polypropylene resin, a polystyrene resin, a polyvinyl acetate resin, a polyester resin, a polyurethane resin, a cellulose-based resin, an acrylic resin, an AS (acrylonitrile-styrene) resin, an ABS (acrylonitrile-butadiene-styrene) resin, a fluorine-based resin, a thermoplastic elastomer, a polyamide resin, a polyimide resin, a polyacetal resin, a polycarbonate resin, a modified polyphenylene ether resin, a polyethylene terephthalate resin, a polybutylene terephthalate resin, a polylactic acid-based resin, a cyclic polyolefin resin, and a polyphenylene sulfide resin. Among these, a cellulose-based resin is preferred, and a triacetyl cellulose resin, a polycarbonate resin, and a polyethylene terephthalate resin are more preferred.

The thickness of the resin substrate is also not particularly limited, and is preferably 10 μm or more, and more preferably 20 μm or more, from the viewpoint of productivity. The thickness is preferably 100 μm or less, and more preferably 80 μm or less, from the viewpoint of designability.

The diffusion layer can be obtained by, for example, coating the resin substrate with a diffusion layer composition, followed by drying, the diffusion layer composition being obtained by dispersing, in a solution in which a polymer resin as a binder is dissolved, a particulate substance having at least anti-glare properties in itself.

Examples of the particulate substance having anti-glare properties include inorganic fine particles such as silica, clay, talc, calcium carbonate, calcium sulfate, barium sulfate, aluminum silicate, titanium oxide, synthetic zeolite, alumina, and smectite, and organic fine particles made of a styrene resin, a urethane resin, a benzoguanamine resin, a silicone resin, an acrylic resin, or the like.

In addition, as the polymer resin as a binder, polymer resins such as a polyester-based resin, an acrylic resin, an acrylic urethane-based resin, a polyester acrylate-based resin, a polyurethane-based acrylate resin, an epoxy acrylate-based resin, and a urethane-based resin can be used. From the viewpoint of film hardness, the polymer resin as a binder is preferably an acrylic resin.

As the anti-glare film, a commercially available product may be used. Examples of a commercially available anti-glare film include an anti-glare PET film and an anti-glare TAC film. Examples of the anti-glare PET film include trade name: BHC-III and EHC-30a manufactured by Higashiyama Film Co., Ltd., and those manufactured by REIKO Co., Ltd. As the anti-glare TAC film, an anti-glare TAC film (trade name: VZ50 manufactured by TOPPAN TOMOEGAWA Optical Films Co., Ltd.) or the like is used.

In the case where one surface of the diffusion layer in the anti-glare film has an irregular shape, the surface of the anti-glare film has an irregular shape due to the irregular shape of the diffusion layer. For example, at least one or more selected from Sa, Sdr, Sdq, and Spc of the anti-glare film in the second embodiment may be similar to the preferred Sa, Sdr, Sdq, and Spc of the anti-reflective film-attached transparent substrate in the first embodiment. In addition, the haze of the anti-glare film in the second embodiment may be similar to the preferred haze of the anti-reflective film-attached transparent substrate in the first embodiment.

The shape of the anti-glare film is generally the same as the shape of the main surface of the unit panel or the transparent substrate to which the anti-glare film is attached. In the case where a part of the main surface to which the anti-glare film is attached is not flat, or in the case where the anti-glare properties are not imparted to a portion having a specific function such as a camera, the shape of the anti-glare film may be a shape processed such that the anti-glare film is not attached to a specific region on the main surface. For the same reason, a part of the anti-glare film may have a region having no diffusion layer.

### (Adhesive)

In order to attach the anti-glare film to the unit panel or the transparent substrate, an adhesive is preferably used as necessary.

Examples of the adhesive include an acrylic adhesive, a silicone-based adhesive, and a urethane-based adhesive. From the viewpoint of durability, the adhesive is preferably an acrylic adhesive. The adhesive may be used by being applied to the surface of the anti-glare film having no diffusion layer, or may be used by being applied to the surface of the transparent substrate to which the anti-glare film is attached. From the viewpoint of durability, it is preferred to apply an adhesive to the anti-glare film. An adhesive formed in a sheet shape or the like in advance may be used. In the case where the resin substrate of the anti-glare film has a self-adsorption property, the anti-glare film may be attached to the transparent substrate without using an adhesive. Note that, a commercially available anti-glare film that already has an adhesive may be used.

### (Transparent Substrate)

The anti-glare film includes a resin substrate. If necessary, the anti-glare film may be attached to a transparent substrate other than the resin substrate constituting the anti-glare film to form an anti-glare film-attached transparent substrate, which may then be arranged on the display surface side of the unit panel. In the case of arranging the anti-glare film-attached transparent substrate on the display surface side of the unit panel, preferred embodiments of the transparent substrate in the anti-glare film-attached transparent substrate are similar to the preferred embodiments of the transparent substrate in the first embodiment.

### (Barrier Layer)

In the case where the anti-glare film further includes an anti-reflective film, the anti-glare film preferably includes a barrier layer between the diffusion layer and the anti-reflective film. Preferred embodiments of the barrier layer in the second embodiment are similar to those of the barrier layer in the first embodiment.

### (Anti-Reflective Film)

The anti-glare film may include an anti-reflective film. In this case, the anti-glare film including an anti-reflective film can also be regarded as an anti-reflective film-attached transparent substrate, which includes a diffusion layer and an anti-reflective film on a transparent substrate (a resin substrate in the anti-glare film). In the second embodiment, such an anti-reflective film-attached transparent substrate is arranged on the display surface side of the unit panel, and the anti-glare film may be disposed on the display surface side of the unit panel. The anti-reflective film is preferably provided on the diffusion layer, that is, on the side opposite to the transparent substrate viewed from the diffusion layer. Note that, as described above, another layer such as a barrier layer may be provided between the diffusion layer and the anti-reflective film, and the diffusion layer and the anti-reflective film do not need to be in contact with each other. The specific configuration of the anti-reflective film is not particularly limited as long as it is capable of preventing the light reflection, and may be, for example, an anti-reflective film same as the anti-reflective film exemplified in the first embodiment.

### (Antifouling Film)

The anti-glare film-attached transparent substrate may include an antifouling film from the viewpoint of protecting the outermost surface. The antifouling film is preferably provided, for example, on the outermost surface of the anti-glare film-attached transparent substrate, on the side opposite to the transparent substrate viewed from the diffusion layer. Specific materials and preferred embodiments of the antifouling film in the second embodiment are similar to those of the antifouling film in the first embodiment.

### (Configuration of Tiling Display)

The number of unit panels constituting the tiling display and the size of the tiling display in the second embodiment are not particularly limited, and preferred embodiments are similar to those of the tiling display in the first embodiment.

The tiling display may be the tiling display according to the second embodiment, and may also be the tiling display according to the first embodiment. In this case, in the tiling display according to the second embodiment, two adjacent unit panels each include an anti-reflective film-attached transparent substrate and satisfy the above condition 1.

### (Method for Producing Tiling Display)

A method for producing a tiling display according to the second embodiment of the present invention is a method for producing a tiling display obtained by arranging a plurality of unit panels, each including an anti-glare film on a display surface side, and the method includes arranging the unit panels such that the unit panels adjacent to each other satisfy the above condition 2 (step A21).

When adjacent unit panels in the tiling display are arranged to satisfy the condition 2, the variation in degree of anti-glare properties is reduced and the color deviation is reduced between these unit panels.

In the step A21, examples of the method of arranging unit panels such that adjacent unit panels satisfy the condition 2 include a method of preparing a plurality of unit panels obtained by arranging (attaching) anti-glare films such that any one direction on the anti-glare film (for example, one of the directions parallel to the MD) is parallel to any one direction on the main surface of the unit panel (for example, the longitudinal direction), and arranging the unit panels. That is, it is preferable to prepare and arrange unit panels such that the directions of the anti-glare films in adjacent unit panels during production are aligned with each other on the main surface of the tiling display, or the slope is relatively small. Alternatively, the L* values at −15° in a plurality of directions on the unit panel or the direction where the L* value is maximum is determined in advance, and the unit panels may be arranged based on the determination result, to make adjacent unit panels satisfy the condition 2. The method of determining the a* and b* may be a method of determining information (measured values or the like) that has been measured and recorded in advance, or a method of measuring and determining the a* and b* each time.

When the number of the unit panels constituting the tiling display is three or more, it is more preferable to arrange the unit panels such that in the obtained tiling display, all combinations of two adjacent unit panels are the combination of unit panels satisfying the condition 2.

A specific method of arranging a plurality of unit panels to form a tiling display is not particularly limited, and any method known in the art for tiling displays can be used. For example, the tiling display may be formed by the method exemplified as the method for producing a tiling display according to the first embodiment.

### (Method for Maintaining Tiling Display)

A method for maintaining a tiling display according to the second embodiment of the present invention is a method for maintaining a tiling display obtained by arranging a plurality of unit panels, each including an anti-glare film on a display surface side, and the method includes: selecting a unit panel to be replaced from the unit panels constituting the tiling display (step B21); and replacing the unit panel to be replaced such that a unit panel after replacement and at least one adjacent unit panel adjacent to the unit panel to be replaced satisfy the above condition 2 (step B22).

In the step B21, a unit panel to be replaced is selected from the unit panels constituting the tiling display. The step B21 is similar to the step B11 in the method for maintaining a tiling display according to the first embodiment.

In the step B22, the unit panel to be replaced is replaced such that a unit panel after replacement and at least one adjacent unit panel adjacent to the unit panel to be replaced satisfy the above condition 2. The “replacement” as used herein includes replacement of a whole unit panel with another unit panel, and replacement of a part of a unit panel, such as replacement of only the anti-glare film in the unit panel. Examples of specific method of replacing the unit panel to be replaced so as to satisfy the above condition 2 include determining a direction of attaching the anti-glare film in each unit panel for unit panels that can be used for replacement and adjacent unit panels thereof, and replacing the unit panel based on the determination result. Alternatively, the L* values at −15° in a plurality of directions on the unit panel or the direction where the L* value is maximum is determined in advance, and the unit panel may be replaced based on the determination result. The method of determining the a* and b* may be a method of determining information (measured values or the like) that has been measured and recorded in advance, or a method of measuring and determining the a* and b* each time.

With the method for maintaining a tiling display according to the second embodiment of the present invention, when replacing some of unit panels in a tiling display, a color deviation in the tiling display after replacement can be reduced.

Note that, in the case where there are a plurality of unit panels adjacent to one unit panel to be replaced, by performing the step B22 on at least one of the adjacent unit panels, the color difference between the adjacent unit panel and the unit panel after replacement is reduced. It is more preferable to perform the step B22 on all of the adjacent unit panels, since this reduces the color differences between all of the adjacent unit panels and the unit panel after replacement.

### EXAMPLES

Hereinafter, the present invention is described in detail with reference to Examples, but the present invention is not limited thereto.

### Example 1 and Example 2

The following Example 1 and Example 2 are examples according to the first embodiment described above.

Anti-reflective film-attached transparent substrates 1 to 3 and unit panels 1 to 3 each including the same were prepared, and these were arranged in combination to form a tiling display, which was then evaluated. The tiling display including a combination of the unit panels 1 and 2 (the tiling display in Example 1) corresponds to Inventive Example, and the tiling display including a combination of the unit panels 1 and 3 (the tiling display in Example 2) corresponds to Comparative Example.

### Evaluation

### (a*, b*, and L* of Diffusely Reflected Light at Each Angle)

The a*, the b*, and the L* of the diffusely reflected light at each angle were measured for the main surface on the display surface side of the unit panel or for the anti-reflective film-attached transparent substrate alone by using the following method. The measurement for the main surface on the display surface side of the unit panel was performed with the screen turned off. In addition, in the measurement for the anti-reflective film-attached transparent substrate alone, a black tape (“KUKKIRI MIERU” manufactured by TOMOEGAWA CORPORATION) was attached to the main surface (the other main surface) of the anti-reflective film-attached transparent substrate not having the diffusion layer or the anti-reflective film to eliminate reflection on the other main surface.

A light source was incident on the main surface (one main surface) of the anti-reflective film-attached transparent substrate having the diffusion layer and the anti-reflective film at an incident angle of 45°. The reflectance at a visible light wavelength was measured for diffusely reflected lights at angles of −15°, 15°, and 25° with respect to the specularly reflected light, and the a*, the b* and the L* under a D65 light source were calculated (diffusion reflection color). Note that, the measurement was performed using CM-M6 manufactured by Konica Minolta, Inc.

### (SCI and SCE)

The reflection colors (L*, a*, and b*) on the main surface on the display surface side of the unit panel or the anti-reflective film-attached transparent substrate alone were measured by the SCI method and the SCE method. All measurements were performed using a spectrophotometer (trade name: CM-26d manufactured by Konica Minolta, Inc.) in according to the method specified in JIS Z 8722 (2009). Note that, in the SCE method, among the reflected lights when a light is incident on an object, the specularly reflected light is eliminated and only the diffusely reflected light is measured, whereas in the SCI method, total reflected lights including the specularly reflected light are measured.

The measurement for the main surface on the display surface side of the unit panel was performed with the screen turned off. In addition, in the measurement for the anti-reflective film-attached transparent substrate alone, a black tape (“KUKKIRI MIERU” manufactured by TOMOEGAWA CORPORATION) was attached to the main surface (the other main surface) of the anti-reflective film-attached transparent substrate not having the diffusion layer or the anti-reflective film to eliminate reflection on the other main surface.

### (Haze)

The haze value (transmitted haze) of the anti-reflective film-attached transparent substrate was measured using a haze meter (HZ-V3 manufactured by Suga Test Instruments Co., Ltd.) according to JIS K 7136:2000.

### (Luminous Transmittance: Y)

In the anti-reflective film-attached transparent substrate, the luminous transmittance (Y) on the outermost surface of the anti-reflective film was measured according to the method specified in JIS Z 8701 (1999). Note that, in the present description, the luminous transmittance (Y) on the outermost surface of the anti-reflective film was taken as the luminous transmittance (Y) of the anti-reflective film-attached transparent substrate. Specifically, of two main surfaces of the transparent substrate, a black tape was attached to the other main surface, which was not the one facing the anti-reflective film, to eliminate back surface reflection. In this state, the spectral transmittance was measured using a spectrophotometer (trade name: SolidSpec-3700 manufactured by Shimadzu Corporation), and the luminous transmittance (a stimulus value Y specified in JIS Z 8701 (1999)) was obtained by calculation.

### (Color Deviation Evaluation)

96 anti-reflective film-attached transparent substrates produced under the same conditions as those for the anti-reflective film-attached transparent substrate 1 in the unit panel 1 were prepared. Specifically, 96 anti-reflective film-attached transparent substrates were prepared under the conditions for the anti-reflective film-attached transparent substrate 1 and by slightly changing the thickness of each layer from these conditions. Then, a black tape (“KUKKIRI MIERU” manufactured by TOMOEGAWA CORPORATION) was attached to the main surface (the other main surface) not having the diffusion layer or the anti-reflective film, and then these anti-reflective film-attached transparent substrates were arranged (tiled) in a matrix of 12 pieces vertically and 8 pieces horizontally with no gaps. The color deviation of the anti-reflective film-attached transparent substrate after tiling was visually evaluated according to the following criteria, and classified into two levels, “good” and “poor”. Thereafter, one each of “good” and “poor” samples with no black tape attached to the back surface were prepared. The “good” sample was used as the anti-reflective film-attached transparent substrate 2 in the unit panel 2, and the “poor” sample was used as the anti-reflective film-attached transparent substrate 3 in the unit panel 3. The anti-reflective film-attached transparent substrates 1 to 3 were arranged on a display surface side of a self-luminous OLED display (Pixel 6 Pro manufactured by Google LLC) by being attached with a transparent adhesive such that the surface having the anti-reflective film faced the display surface side, thereby forming the unit panels 1 to 3. For each unit panel, the SCI, the SCE, and the diffusion reflection color at each angle were obtained.

Good: when a white LED illumination glares on the main surface (one main surface) of the anti-reflective film-attached transparent substrate having the diffusion layer and the anti-reflective film and the main surface was viewed from various angles, the white illumination glared on the anti-reflective film-attached transparent substrate appeared nearly achromatic, and the difference in color between substrates was not noticeable.

Poor: when a white LED illumination glares on the main surface (one main surface) of the anti-reflective film-attached transparent substrate having the diffusion layer and the anti-reflective film and the main surface was viewed from various angles, the difference in color from the surroundings was noticeable.

Next, the unit panel 1 and the unit panel 2 were arranged side by side to form the tiling display in Example 1 consisting of two unit panels. In addition, the unit panel 1 and the unit panel 3 were arranged side by side to form the tiling display in Example 2 consisting of two unit panels. For each tiling display, the color deviations when viewed from the front and viewed obliquely were evaluated according to the following criteria.

“No”: when visually observing the tiling display, no difference in color tone (reflection color) was found between unit panels.

“Yes”: when visually observing the tiling display, a difference in color tone (reflection color) between unit panels was found, and the color deviations was noticeable.

In addition, when the a* and the b* of the diffusely reflected light at each angle for the unit panel 1 were defined as aₓ* and bₓ*, and the a* and the b* of the diffusely reflected light at each angle for each example were defined as a_{y}* and b_{y}*, Δa*b* at each angle was calculated. The Δa*b* was calculated similarly for the SCI and the SCE.

### (Anti-Reflective Film-Attached Transparent Substrate 1)

An anti-reflective film was formed on an anti-glare PET film having a diffusion layer formed on one main surface of a transparent substrate, to produce an anti-reflective film-attached transparent substrate, by using the following method. Note that, as the transparent substrate, a resin substrate was used as to be described later.

### (Transparent Substrate and Diffusion Layer)

An anti-glare PET film measuring 50 mm in length, 50 mm in width, and 0.1 mm in thickness (manufactured by REIKO Co., Ltd., Sa: 0.259 μm, Sdr: 0.0620, Sdq: 0.361, Spc: 1703 (1/mm), haze value: 60%) was used.

### (Formation of Barrier Layer)

Next, a SiN layer having a thickness shown in Table 1 was formed as a barrier layer on the diffusion layer. For example, in Example 1, the barrier layer has a thickness of 9 nm.

As the barrier layer, a silicon target was used in a digital sputtering method, the pressure was kept at 0.2 Pa with an argon gas, pulse sputtering was performed under conditions of a frequency of 100 kHz, a power density of 10.0 W/cm², and a reverse pulse width of 3 μsec to form a silicon film having a minute thickness, and immediately thereafter, nitridation with a nitrogen gas was performed, which was repeated at a high speed to form a silicon nitride film, and a layer made of a silicon nitride (SiNₓ) having a predetermined thickness was formed. Here, a nitrogen flow rate during the nitridation with a nitrogen gas was 800 sccm, and an input power of a nitridation source was 600 W.

### (Formation of Anti-Reflective Film)

Next, a NMWO layer (high refractive index layer) and a SiO layer (low refractive index layer) were alternately formed on the barrier layer to form an anti-reflective film having the film configuration shown in Table 1. Note that, the NMWO layer means a mixed oxide layer containing Nb, Mo, and W. For example, the film configuration of the anti-reflective film in Example 1 in Table 1 means that a 4 nm NMWO layer is formed on the barrier layer, then a 40 nm SiO layer is formed, then a 44 nm NMWO layer is formed, then a 15 nm SiO layer is formed, then a 46 nm NMWO layer is formed, and then a 87 nm SiO layer is formed, to form an anti-reflective film having a film configuration of six layers. The film-forming methods for the SiO layer and the NMWO layer are as follows.

### (Formation of NMWO Layer)

In a digital sputtering method, a target obtained by mixing and sintering niobium, molybdenum, and tungsten in a mass ratio of 24:30:46 was used, the pressure was kept at 0.2 Pa with an argon gas, pulse sputtering was performed under conditions of a frequency of 100 kHz, a power density of 10.0 W/cm², and a reverse pulse width of 3 μsec to form a metal film having a minute thickness, and immediately thereafter, oxidation with an oxygen gas was performed, which was repeated at a high speed to form an oxide film, so as to form a NMWO layer having a predetermined thickness. Note that, when the composition of the NMWO layer formed by this method was measured by X-ray photoelectron spectroscopy (XPS) depth direction composition analysis using argon ion sputtering, excluding oxygen, Nb was 31.5 at %, Mo was 38.1 at %, W was 30.5 at %, and the content of group B elements was 24 wt %.

### (Formation of SiO Layer)

A silicon target was used in a digital sputtering method, the pressure was kept at 0.2 Pa with an argon gas, pulse sputtering was performed under conditions of a frequency of 100 kHz, a power density of 10.0 W/cm², and a reverse pulse width of 3 μsec to form a silicon film having a minute thickness, and immediately thereafter, oxidation with an oxygen gas was performed, which was repeated at a high speed to form a silicon oxide film, and a layer made of a silicon oxide [silica (SiOₓ)] having a predetermined thickness was formed. Here, an oxygen flow rate during the oxidation with an oxygen gas was 500 sccm, and an input power of an oxidation source was 1000 W.

### (Formation of Antifouling Film)

KY-185 (trade name, manufactured by Shin-Etsu Chemical Co., Ltd.) as a fluorine-containing organosilicon compound was charged into a metal crucible (evaporation source) and heated to evaporate at 230° C. to 350° C. The evaporated particles evaporated and diffused into a vacuum chamber in which the substrate was installed, and adhered on the surface of the substrate. A 4-nm thick antifouling film was formed while a vapor deposition rate was monitored by controlling with a crystal oscillator.

### (Anti-Reflective Film-Attached Transparent Substrates 2 and 3)

The anti-reflective film-attached transparent substrates 2 and 3 were obtained in the same manner as the anti-reflective film-attached transparent substrate 1. However, due to a variation in thickness caused by the film-forming process, the thickness of each layer in the anti-reflective film and the like in the anti-reflective film-attached transparent substrates 2 and 3 are slightly different from that in the anti-reflective film-attached transparent substrate 1.

The anti-reflective film-attached transparent substrates 1 to 3 and the unit panels 1 to 3 were subjected to the above evaluation. The results are shown in Table 1. Here, the results of evaluating the Δa*b* and the difference in reflection color when the unit panels 2 and 3 are arranged next to the unit panel 1 correspond to the results of evaluating the tiling displays in Examples 1 and 2, respectively.

TABLE 1

| | | | Anti-reflective film- | | | Anti-reflective film- | | | Anti-reflective film- | | |
|---|---|---|---|---|---|---|---|---|---|---|---|
| | | | attached transparent | | | attached transparent | | | attached transparent | | |
| | | | substrate 1/unit panel 1 | | | substrate 2/unit panel 2 | | | substrate 3/unit panel 3 | | |
| Number of layers in anti-reflective film | | | 6 | | | 6 | | | 6 | | |
| Luminous transmittance Y (D65) (%) | | | 75 | | | 75 | | | 75 | | |
| Transmitted haze (%) | | | 60 | | | 60 | | | 60 | | |
| High refractive index layer | | | NMWO | | | NMWO | | | NMWO | | |
| Diffusion reflection color | | | Green | | | Green | | | Green | | |
| Antifouling film | | KY-185 (nm) | 4 | | | Basic thickness is same as that of anti-reflective | | | | | |
| Anti-reflective film | 6 | Low refractive | 87 | | | film-attached transparent substrate 1, but there is | | | | | |
| | | index layer (nm) | | | | some variation in thickness due to film-forming | | | | | |
| | 5 | High refractive | 46 | | | process | | | | | |
| | | index layer (nm) | | | | | | | | | |
| | 4 | Low refractive | 15 | | | | | | | | |
| | | index layer (nm) | | | | | | | | | |
| | 3 | High refractive | 44 | | | | | | | | |
| | | index layer (nm) | | | | | | | | | |
| | 2 | Low refractive | 40 | | | | | | | | |
| | | index layer (nm) | | | | | | | | | |
| | 1 | High refractive | 4 | | | | | | | | |
| | | index layer (nm) | | | | | | | | | |
| Barrier layer | | SiN (nm) | 9 | | | | | | | | |
| Substrate | | | AGPET from REIKO | | | AGPET from REIKO | | | AGPET from REIKO | | |
| Reflection color (anti- | | Index | L* | a* | b* | L* | a* | b* | L* | a* | b* |
| reflective film-attached | | SCI | 7.3 | −2.1 | 0.6 | 7.0 | −1.5 | −0.7 | 10.1 | −1.8 | −1.6 |
| transparent substrate | | SCE | 5.9 | −2.1 | 0.5 | 5.6 | −1.6 | −0.6 | 8.6 | −1.8 | −1.8 |
| alone) (D65) | | | | | | | | | | | |
| Diffusion reflection | | Index | L* | a* | b* | L* | a* | b* | L* | a* | b* |
| color (anti-reflective | | −15° | 52.9 | −2.9 | 2.2 | 53.6 | −0.1 | 0.1 | 58.5 | −0.7 | −3.3 |
| film-attached | | 15° | 26.7 | −6.3 | 4.2 | 26.8 | −5.2 | 1.3 | 32.2 | −5.2 | −1.7 |
| transparent substrate | | 25° | 13.3 | −6.2 | 3.5 | 13.1 | −5.0 | 0.9 | 17.8 | −3.3 | −1.8 |
| alone) (D65) | | 45° | 2.7 | −2.1 | 0.5 | 2.6 | −1.4 | −0.3 | 4.3 | 0.7 | −1.0 |
| Color deviation | Reflection | SCI | 0.0 | | | 1.7 | | | 2.2 | | |
| Δa*b* (anti- | color | SCE | 0.0 | | | 1.4 | | | 2.3 | | |
| reflective film- | Diffusion | −15° | 0.0 | | | 9.8 | | | 5.9 | | |
| attached | reflection | 15° | 0.0 | | | 4.0 | | | 6.0 | | |
| transparent | color | 25° | 0.0 | | | 1.3 | | | 3.2 | | |
| substrate alone) | | | | | | | | | | | |

| Difference in reflection color | Viewed from | — | | | No | | | No | | |
|---|---|---|---|---|---|---|---|---|---|---|
| when arranged next to anti- | front | | | | | | | | | |
| reflective film-attached | Viewed | — | | | Yes | | | Yes | | |
| transparent substrate 1 | obliquely | | | | | | | | | |
| Reflection color (unit panel) | Index | L* | a* | b* | L* | a* | b* | L* | a* | b* |
| (D65) | SCI | 10.0 | −1.9 | 1.4 | 10.2 | −1.3 | 0.1 | 12.5 | −2.2 | 0.3 |
| | SCE | 7.8 | −2.3 | 1.3 | 8.0 | −1.7 | 0.0 | 10.5 | −2.4 | 0.0 |
| Diffusion reflection color | Index | L* | a* | b* | L* | a* | b* | L* | a* | b* |
| (unit panel) (D65) | −15° | 55.8 | −1.9 | 3.4 | 55.1 | −1.4 | 1.4 | 60.0 | −1.5 | −2.5 |
| | 15° | 30.6 | −4.5 | 4.5 | 30.6 | −5.0 | 2.7 | 35.0 | −5.2 | −0.5 |
| | 25° | 15.5 | −4.8 | 3.8 | 15.3 | −4.9 | 2.2 | 19.4 | −3.9 | −0.6 |

| | | | | | |
|---|---|---|---|---|---|
| Color deviation | Reflection | SCI | 0.0 | 1.6 | 1.2 |
| Δa*b* (unit panel) | color | SCE | 0.0 | 1.6 | 1.3 |
| | Diffusion | −15° | 0.0 | 2.2 | 5.9 |
| | reflection | 15° | 0.0 | 2.1 | 5.1 |
| | color | 25° | 0.0 | 1.6 | 4.5 |

| | | | | |
|---|---|---|---|---|
| Difference in reflection color | Viewed from | — | No | No |
| when arranged next to unit | front | | | |
| panel 1 | Viewed | — | No | Yes |
| | obliquely | | | |

As can be seen from the results in Table 1, in a tiling display consisting of unit panels in Example 1 and Example 2 in which two adjacent unit panels satisfy the above condition 1 (tiling display in Example 1), the difference in reflection color after tiling is not noticed.

### Examples 3 to 5

The following Example 3 to Example 5 are examples according to the second embodiment described above.

Unit panels 4 to 7 were prepared, and were arranged in combination to form a tiling display, which was then evaluated. The tiling display including a combination of the unit panels 4 and 5 (the tiling display in Example 3) corresponds to Inventive Example, and the tiling display including a combination of the unit panels 4 and 6 (the tiling display in Example 4) and the tiling display including a combination of the unit panels 4 and 7 (the tiling display in Example 5) correspond to Comparative Examples.

### Evaluation

### (L* of Diffusely Reflected Light)

For the anti-reflective film-attached transparent substrate used in each unit panel, the L* of the diffusely reflected light was measured by using the following method. Note that, a black tape (“KUKKIRI MIERU” manufactured by TOMOEGAWA CORPORATION) was attached to the main surface of the anti-reflective film-attached transparent substrate on the side not having the diffusion layer viewed from the transparent substrate, thereby eliminating reflection on the main surface on the side not having the diffusion layer.

A light source was incident on the main surface (one main surface) of the anti-reflective film-attached transparent substrate having the diffusion layer and arranged on the display surface side of the unit panel at an incident angle of 45°. The reflectance at a visible light wavelength was measured for the diffusely reflected light at an angle of −15° with respect to the specularly reflected light, and the L* under a D65 light source were calculated (diffusion reflectance). Note that, the measurement was performed using CM-M6 manufactured by Konica Minolta, Inc. In addition, the measurement using a spectrophotometer CM-26d manufactured by Konica Minolta, Inc. also had similar results, although the absolute values of the L* values were different.

The L* value was measured while one direction on the main surface of the anti-reflective film-attached transparent substrate (a direction corresponding to the 0° direction in the obtained tiling display) was defined as the 0° direction and 36 directions at an interval of 10° to the 360° direction were defined as the incident directions. Based on this result, the angle in the direction where the L* value of each unit panel in the obtained tiling display according to the condition 2 was maximum was specified.

### (Unit Panel 4)

An anti-glare PET film (manufactured by REIKO Co., Ltd., Sa: 0.259 μm, Sdr: 0.0620, Sdq: 0.361, Spc: 1703 (1/mm), haze value: 60%) was used as the anti-glare film, and a barrier layer, an anti-reflective film, and an antifouling layer were formed on the diffusion layer to obtain an anti-reflective film-attached transparent substrate 4. The barrier layer, the anti-reflective film, and the antifouling layer were formed in the same method as in the anti-reflective film-attached transparent substrate 1. The obtained anti-reflective film-attached transparent substrate 4 was attached to a display surface side of a self-luminous OLED display (Pixel 6 Pro manufactured by Google LLC). At this time, the anti-reflective film-attached transparent substrate 4 was attached such that the MD direction of the anti-glare film was aligned with an upward direction when viewed from the front of the display surface of the display (hereinafter also referred to as a reference direction), thereby obtaining the unit panel 4.

### (Unit Panel 5 and Example 3)

An anti-glare PET film (manufactured by REIKO Co., Ltd., Sa: 0.259 μm, Sdr: 0.0620, Sdq: 0.361, Spc: 1703 (1/mm), haze value: 60%) was used as the anti-glare film, and a barrier layer, an anti-reflective film, and an antifouling layer were formed on the diffusion layer to obtain an anti-reflective film-attached transparent substrate 5. The barrier layer, the anti-reflective film, and the antifouling layer were formed in the same method as in the anti-reflective film-attached transparent substrate 4. The obtained anti-reflective film-attached transparent substrate 5 was attached to a display surface side of a self-luminous OLED display (Pixel 6 Pro manufactured by Google LLC). At this time, the anti-reflective film-attached transparent substrate 5 was attached such that the MD direction of the anti-glare film was aligned with the upward direction when viewed from the front of the display surface of the display (reference direction), thereby obtaining the unit panel 5. The unit panels 4 and 5 were arranged adjacent to each other to obtain the tiling display in Example 3. Note that, the shape of the main surface of each of the unit panels 4 to 7 was approximately rectangular, and in the tiling displays in Examples 3 to 5, two adjacent unit panels were arranged to share one side at the boundary. In each tiling display, the unit panels were arranged such that reference directions when anti-reflective film-attached transparent substrates were attached to respective unit panels were the same direction within one tiling display. That is, in the tiling display in Example 3, the unit panel 4 and the unit panel 5 were arranged such that the reference direction of the unit panel 4 was the same as the reference direction of the unit panel 5 (for example, both were the upward direction when viewed from the front of the main surface of the tiling display).

### (Unit Panel 6 and Example 4)

The anti-reflective film-attached transparent substrate 5 was used to be attached to a display surface side of a self-luminous OLED display (Pixel 6 Pro manufactured by Google LLC). At this time, the anti-reflective film-attached transparent substrate 5 was attached such that the MD direction of the anti-glare film was rotated 90° clockwise with respect to the upward direction when viewed from the front of the display surface of the display (reference direction), thereby obtaining the unit panel 6. The unit panels 4 and 6 were arranged adjacent to each other to obtain the tiling display in Example 4.

### (Unit Panel 7 and Example 5)

The anti-reflective film-attached transparent substrate 5 was used to be attached to a display surface side of a self-luminous OLED display (Pixel 6 Pro manufactured by Google LLC). At this time, the anti-reflective film-attached transparent substrate 5 was attached such that the MD direction of the anti-glare film was rotated 180° clockwise with respect to the upward direction when viewed from the front of the display surface of the display (reference direction), thereby obtaining the unit panel 7. The unit panels 4 and 7 were arranged adjacent to each other to obtain the tiling display in Example 5.

### Evaluation Results

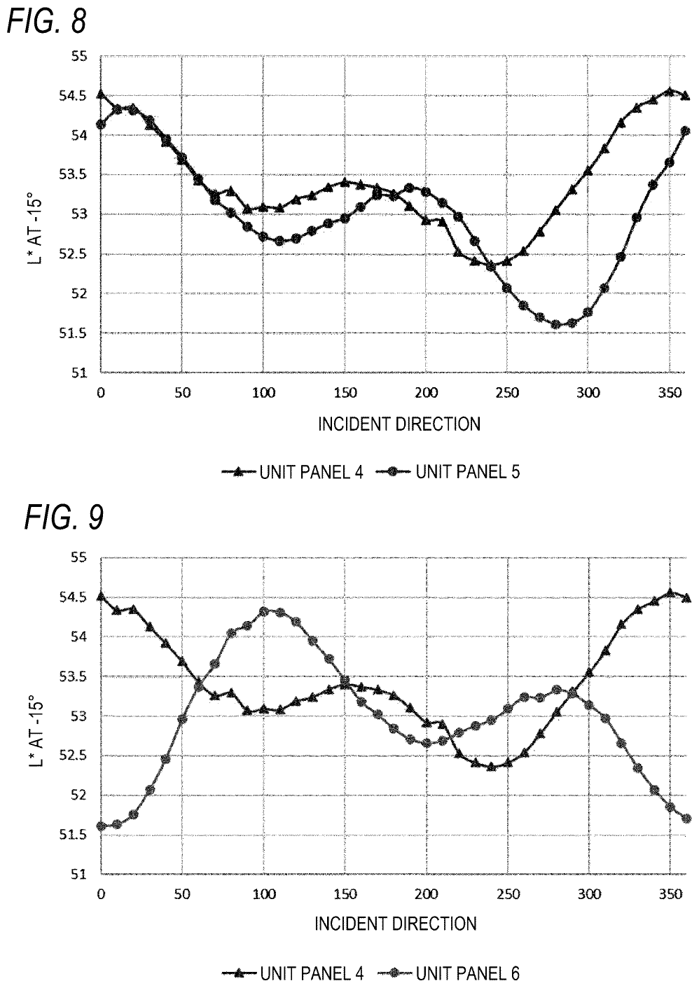

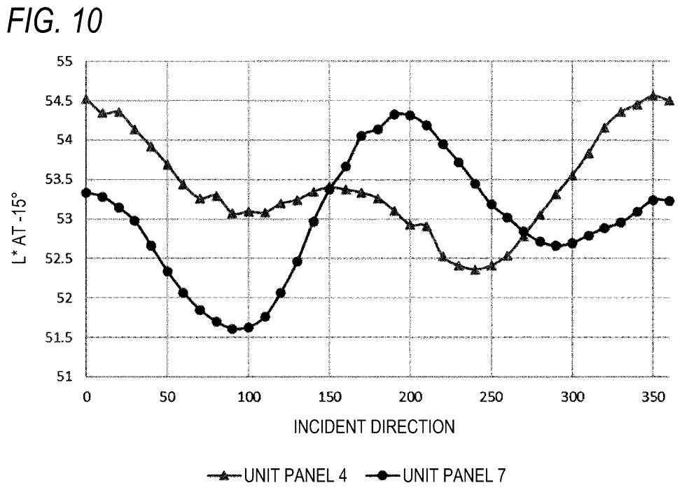

FIG. 8 to FIG. 10 show the results of the above measurement for each tiling display. That is, FIG. 8 is a diagram showing the L* values in 36 directions of each unit panel (unit panels 4 and 5) in the tiling display in Example 3, FIG. 9 is a diagram showing the L* values in 36 directions of each unit panel (unit panels 4 and 6) in the tiling display in Example 4, and FIG. 10 is a diagram showing the L* values in 36 directions of each unit panel (unit panels 4 and 7) in the tiling display in Example 5. Note that, the measured L* value itself is a value measured for the anti-reflective film-attached transparent substrate alone for the anti-reflective film-attached transparent substrate in each unit panel, and even when similar measurement is performed after the unit panel is formed, the directivity of the L* value depending on the incident direction does not change.

In the tiling display in Example 3, for the unit panel 4, the angle in the direction where the L* value was maximum was 350°, and the maximum L* value was 54.56. For the unit panel 5, the angle in the direction where the L* value was maximum was 10°, and the maximum L* was 54.32. The difference between the angles in the directions where the L* value was maximum was 20°.

In the tiling display in Example 4, for the unit panel 4, the angle in the direction where the L* value was maximum was 350°, and the maximum L* value was 54.56. For the unit panel 6, the angle in the direction where the L* value was maximum was 100°, and the maximum L* was 54.32. The difference between the angles in the directions where the L* value was maximum was 120°.

In the tiling display in Example 5, for the unit panel 4, the angle in the direction where the L* value was maximum was 350°, and the maximum L* value was 54.56. For the unit panel 7, the angle in the direction where the L* value was maximum was 190°, and the maximum L* was 54.32. The difference between the angles in the directions where the L* value was maximum was 160°.

When the tiling display in Example 3 was visually observed, no difference in color tone (reflection color) was found between the unit panels either when viewed from the front or viewed obliquely. When the tiling displays in Example 4 and Example 5 were visually observed from various angles, a difference in color tone (reflection color) between unit panels was found, and the color deviations was noticeable.

Although various embodiments have been described above with reference to the drawings, it is needless to say that the present invention is not limited to such examples. It is obvious for a person skilled in the art that various modifications and variations can be made within the category described in the scope of claims and it is understood that such modifications and variations naturally belong to the technical scope of the present invention. Further, the components described in the above embodiment may be combined in any manner without departing from the spirit of the invention.

Note that, the present application is based on a Japanese patent application (Japanese Patent Application No. 2022-064751) filed on Apr. 8, 2022, a Japanese patent application (Japanese Patent Application No. 2022-064752) filed on Apr. 8, 2022, a Japanese patent application (Japanese Patent Application No. 2022-112709) filed on Jul. 13, 2022, and a Japanese patent application (Japanese Patent Application No. 2022-190437) filed on Nov. 29, 2022, contents of which are incorporated herein by reference.

### REFERENCE SIGNS LIST

100, 200 tiling display
5, 5a, 5b, 205, 205a, 205b unit panel
7, 7a, 7b, 207, 207a, 207b main body portion
1, 1a, 1b anti-reflective film-attached transparent substrate
201, 201a, 201b anti-glare film
10 transparent substrate
210 resin substrate
11 one main surface
12 the other main surface
20 black tape
30 anti-reflective film
31, 231 diffusion layer
32 first dielectric layer
34 second dielectric layer
50 light source
60 incident light
61 specularly reflected light
71, 72, 73, 74, 75, 76 diffusely reflected light
80 incident light
81 diffusely reflected light
D1 0° direction
S side shared by two adjacent unit panels
P projection trajectory

1. A tiling display obtained by arranging a plurality of unit panels, each comprising an anti-reflective film-attached transparent substrate on a display surface side,
wherein the anti-reflective film-attached transparent substrate comprises a transparent substrate, a diffusion layer, and an anti-reflective film in this order toward the display surface side, and
two of the unit panels adjacent to each other satisfy the following condition 1:
(Condition 1)
provided that a* and b* of diffusely reflected lights at angles of −15°, 15°, and 25° with respect to a specularly reflected light under a D65 light source when a light source is incident at an incident angle of 45° on a main surface on the display surface side for one unit panel of the two unit panels are defined as aₓ* and bₓ* at respective angles, and a* and b* for the other unit panel measured in the same manner are defined as a_{y}* and b_{y}* at respective angles, Δa*b* at respective angles is 3.0 or less.
$$Δ {a}^{*} {b}^{*} = {( {( {a}_{x}^{*} - {a}_{y}^{*} )}^{2} + {( {b}_{x}^{*} - {b}_{y}^{*} )}^{2} )}^{1 / 2}$$

2. The tiling display according to claim 1, wherein the anti-reflective film-attached transparent substrate has a haze value of 30% or more.

3. A unit panel group for use in a tiling display obtained by arranging a plurality of unit panels, each comprising an anti-reflective film-attached transparent substrate on a display surface side,
wherein the anti-reflective film-attached transparent substrate comprises a transparent substrate, a diffusion layer, and an anti-reflective film in this order toward the display surface side, and
any two unit panels selected from the unit panel group satisfy the following condition 1:
(Condition 1)
provided that a* and b* of diffusely reflected lights at angles of −15°, 15°, and 25° with respect to a specularly reflected light under a D65 light source when a light source is incident at an incident angle of 45° on a main surface on the display surface side for one unit panel of the two unit panels are defined as aₓ* and bₓ* at respective angles, and a* and b* for the other unit panel measured in the same manner are defined as a_{y}* and b_{y}* at respective angles, Δa*b* at respective angles is 3.0 or less.
$$Δ {a}^{*} {b}^{*} = {( {( {a}_{x}^{*} - {a}_{y}^{*} )}^{2} + {( {b}_{x}^{*} - {b}_{y}^{*} )}^{2} )}^{1 / 2}$$

4. The unit panel group according to claim 3, wherein the anti-reflective film-attached transparent substrate has a haze value of 30% or more.

5. The tiling display according to claim 1, wherein the anti-reflective film-attached transparent substrate comprises an anti-glare film as the diffusion layer and the transparent substrate, and the two adjacent unit panels satisfy the following condition 2:
(Condition 2)
a difference between an angle in a direction where an L* value is maximum for one unit panel of the two adjacent unit panels and an angle in a direction where an L* value is maximum for the other unit panel measured in the same manner is 35° or less, as obtained by the following method:
(Method)
in a plane parallel to a main surface of the tiling display, one direction of directions parallel to a side shared by the two adjacent unit panels is defined as a 0° direction, a light source is incident on a main surface on the display surface side of a unit panel to be measured at an incident angle of 45° while changing an incident direction from the 0° direction to a 360° direction at an interval of 10°, an L* value of a diffusely reflected light at an angle of −15° with respect to a specularly reflected light of an incident light under a D65 light source is measured at each incident direction, and an angle in the incident direction where the L* value is maximum is defined as the angle in the direction where the L* value is maximum for the unit panel to be measured.

6. A tiling display obtained by arranging a plurality of unit panels, each comprising an anti-glare film on a display surface side,
wherein two of the unit panels adjacent to each other satisfy the following condition 2:
(Condition 2)
a difference between an angle in a direction where an L* value is maximum for one unit panel of the two adjacent unit panels and an angle in a direction where an L* value is maximum for the other unit panel measured in the same manner is 35° or less, as obtained by the following method:
(Method)
in a plane parallel to a main surface of the tiling display, one direction of directions parallel to a side shared by the two adjacent unit panels is defined as a 0° direction, a light source is incident on a main surface on the display surface side of a unit panel to be measured at an incident angle of 45° while changing an incident direction from the 0° direction to a 360° direction at an interval of 10°, an L* value of a diffusely reflected light at an angle of −15° with respect to a specularly reflected light of an incident light under a D65 light source is measured at each incident direction, and an angle in the incident direction where the L* value is maximum is defined as the angle in the direction where the L* value is maximum for the unit panel to be measured.
